(19) United States
(12) Patent Application Publication
(10) Pub. No.: US 2013/0012087 A1
(43) Pub. Date: Jan. 10, 2013

(54) Cured Organopolysiloxane Resin Film Having Gas Barrier Properties and Method Of Producing The Same

(76) Inventors: Maki Itoh, Edogawa-ku (JP); Michitaka Suto, Odawara-shi (JP); Bizhong Zhu, Midland, MI (US); Dimitris Elias Katsoulis, Midland, MI (US); Ludmil Zambov, Midland, MI (US)

(21) Appl. No.: 13/520,359

(22) PCT Filed: Jan. 7, 2011
(86) PCT No.: PCT/JP2011/050608

§ 371 Date: Sep. 10, 2012

(30) Foreign Application Priority Data
Jan. 7, 2010 (JP) JP2010-002237

(51) Int. Cl. B32B 27/04; C23C 14/06; C23C 16/40; B05D 3/06; C23C 16/34; C23C 16/30

(52) U.S. Cl. 442/71; 428/447; 427/248.1; 427/497; 427/509; 427/525; 427/255.7

(57) ABSTRACT

A cured organopolysiloxane resin film having gas barrier properties comprising a fiber-reinforced film made of a hydrosilylation-cured organopolysiloxane resin and having a transparent inorganic layer selected from silicon oxynitride layer, silicon nitride layer, and silicon oxide layer formed on the fiber-reinforced film wherein a layer of cured organopolysiloxane that contains an organic functional group, silanol group, hydrosilyl group, or an organic group produced by the polymerization of polymerizable organic functional groups is interposed between said fiber-reinforced film and inorganic layer. Also, a method of producing this cured organopolysiloxane resin film having gas barrier properties.

### TECHNICAL FIELD

The present invention relates to a cured organopolysiloxane resin film that exhibits excellent gas barrier properties, in which a transparent inorganic layer selected from the group consisting of a silicon oxynitride layer, silicon nitride layer, and silicon oxide layer is formed on a fiber-reinforced film made of a cured organopolysiloxane resin which is transparent in the visible region. The present invention additionally relates to a method of producing this cured organopolysiloxane resin film having excellent gas barrier properties.

### BACKGROUND ART

Film-type optical elements having various polymeric films as the substrate therein are beginning to be used in, for example, organic EL displays and liquid crystal displays. Moreover, the importance of film-type optical elements is increasing as these displays become thinner and lighter. Paper-type displays have recently become a topic, but this is a technology that will not be accomplished without polymer films.

Polymer films are one of the most successful technologies in the field of polymer materials; the most prominent polymer films are films made transparent by the biaxial stretching of a crystalline polymer film, such as polyethylene, polypropylene, and polyethylene terephthalate, and films of noncrystalline polymers such as polycarbonate and polymethyl methacrylate. All of these polymers are thermoplastic polymers, and free-standing films can be easily produced by adjusting the molecular weight and molecular weight distribution.

However, within the realm of crosslinked polymer films, it is difficult to commercially acquire a free-standing film other than polyimide films, and in practice crosslinked polymer films are often made available formed on an appropriate substrate. Because crosslinked polymers are formed by the crosslinking of a low molecular weight compound or low molecular weight oligomer, the formation of a film is frequently problematic due to the shrinkage produced during crosslinking and the internal stress generated by crosslinking. However, the melt flow seen at high temperatures with thermoplastic resins does not occur as a consequence of the crosslinked structure, thus offering the advantage that substantial deformation does not occur even at or above the glass-transition temperature.

Crosslinking reaction-cured organopolysiloxane resins are well known to exhibit an excellent heat resistance and an excellent optical transparency, and, among their optical properties, a characteristic feature of the cured organopolysiloxane resins is a low birefringence. Low birefringence is an important property for optical materials involved with imaging and is also an important property with regard to lowering the read error in optical recording. An excellent planarity is another characteristic feature of cured organopolysiloxane resin films.

Film-type optical elements have recently been receiving attention for application in particular to organic EL displays and liquid-crystal displays; however, strong gas barrier properties are required of the film substrate for film-type optical elements for organic EL displays and liquid-crystal displays in order to avoid performance degradation due to contact with, inter alia, water vapor or oxygen.

For example, Japanese Patent Application Publication No. [hereinafter referred to as “JP Kokai”] H8-224825 (JP 8-224825 A) [Patent Reference 1] and US 2003/0228475 A1 [Patent Reference 2] disclose a gas barrier film comprising a thin film formed on a plastic film wherein the main component of this thin film is silicon oxide. A transparent, water vapor-barrier film comprising two types of silicon oxynitride layers formed on a resin substrate is disclosed in Japanese Patent No. 3859518 (JP 3859518 B) and JP Kokai 2003-206361 [Patent Reference 3]. A gas barrier laminate comprising a silicon oxynitride layer formed on a resin substrate, e.g., a plastic film, is disclosed in JP Kokai 2004-276564 (JP 2004-276564 A) [Patent Reference 4] and US 2003/0228475 A 1 [Patent Reference 2]. JP Kokai 2006-123306 (JP 2006-123306 A) [Patent Reference 5] discloses a gas barrier laminate comprising a resin layer of which main component is a polyorganosilsesquioxane laminated on the surface of a plastic film and an inorganic compound layer of silicon oxide, silicon oxynitride, silicon oxycarbide, silicon carbide, silicon nitride, or silicon dioxide formed by a vacuum film formation procedure on the resin layer.

However, each of the substrates is a thermoplastic resin film, and as a consequence problems arise such as a poor heat resistance and a large birefringence.

The present inventors therefore attempted to form a silicon oxynitride layer, that is, silicon oxynitride film on a hydrosilylation reaction-cured organopolysiloxane resin film as disclosed in WO 2005/111149 A1 [Patent Reference 6] and a hydrosilylation reaction-cured and fiber-reinforced organopolysiloxane resin film as disclosed in US2008/0051548A1[Patent Reference 7]. However, it was discovered that the silicon oxynitride layer, that is, silicon oxynitride film did not adhere uniformly and that the gas barrier properties, such as the water vapor barrier performance, were inferior.

The present inventors therefore carried out intensive investigations in order to develop a fiber-reinforced film, particularly free-standing film made of a cured organopolysiloxane resin having remarkably high gas barrier properties, comprising a transparent inorganic layer, that is, a transparent inorganic film selected from the group consisting of a silicon oxynitride layer, i.e. that is silicon oxynitride film, silicon nitride layer, i.e. that is silicon nitride film, and silicon oxide layer, i.e. that is silicon oxide film, uniformly formed on a fiber-reinforced film, particularly free-standing film made of a cured organopolysiloxane resin which is transparent in the visible region, wherein this transparent inorganic layer (transparent inorganic film) is firmly adhered to the aforementioned fiber-reinforced film.

As a result of these investigations, the present inventors invented such a fiber-reinforced film, particularly free-standing film made of a cured organopolysiloxane resin having remarkably high gas barrier properties and a method of producing such a fiber-reinforced film, particularly free-standing film made of a cured organopolysiloxane resin having remarkably high gas barrier properties.

### SUMMARY OF THE INVENTION

### Problems to Be Solved by the Invention

An object of the present invention is to provide a fiber-reinforced film, particularly free-standing film made of a cured organopolysiloxane resin that exhibits a remarkably high gas barrier properties due to an firm adherence by a transparent inorganic layer, i.e., transparent inorganic film selected from the group consisting of a silicon oxynitride layer, i.e., silicon oxynitride film, silicon nitride layer, i.e., silicon nitride film, and silicon oxide layer, i.e., silicon oxide film, to a fiber-reinforced film, particularly free-standing film made of a cured organopolysiloxane resin which is transparent in the visible region, and to provide a method of producing said fiber-reinforced film, particularly free-standing film made of a cured organopolysiloxane resin having remarkably high gas barrier properties.

This object is achieved by
“[1] A cured organopolysiloxane resin film having gas barrier properties comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is interposed between the aforementioned fiber-reinforced film and the aforementioned transparent inorganic layer.
[1-1] A cured organopolysiloxane resin film having gas barrier properties according to [1], wherein (a) an organic functional group-containing cured organopolysiloxane layer is selected from the group consisting of (a-1) an organic functional group-containing, and silanol group- and hydrosilyl group-free cured organopolysiloxane layer, (a-2) an organic functional group- and silanol group-containing cured organopolysiloxane layer, and (a-3) an organic functional group- and hydrosilyl group-containing cured organopolysiloxane layer.
[1-2] A cured organopolysiloxane resin film having gas barrier properties according to [1-1], wherein
   (a-1) an organic functional group-containing, and silanol group- and hydrosilyl group-free cured organopolysiloxane layer is an organic functional group-containing, and silanol group- and hydrosilyl group-free cured organopolysiloxane layer produced by a hydrolsilyaltion reaction-crosslinking of (a-1-1) a organic functional group-containing hydrolsilyaltion reaction-curable organopolysiloxane composition,
   (a-2) an organic functional group- and silanol group-containing cured organopolysiloxane layer is an organic functional group- and silanol group-containing cured organopolysiloxane layer produced by a condensation reaction-crosslinking of (a-2-1) a organic functional group- and silicon-bonded hydrolysable groups-containing organosilane or a composition thereof, or is an organic functional group- and silanol group-containing cured organopolysiloxane layer produced by a condensation reaction-crosslinking of (a-2-2) a organic functional group- and silicon-bonded hydrolysable groups-containing organopolysiloxane or a composition thereof,
   (a-3) an organic functional group- and hydrosilyl group-containing cured organopolysiloxane layer is an organic functional group- and residual hydrosilyl group-containing cured organopolysiloxane layer produced by a hydrolsilyaltion reaction-crosslinking of (a-3-1) an organic functional group-containing hydrolsilyaltion reaction-curable organopolysiloxane composition,
   (b) a silanol group-containing cured organopolysiloxane layer free from the organic functional group is an organic functional group-free and silanol group-containing cured organopolysiloxane layer produced by a condensation reaction-crosslinking of (b-1) a organic functional group-free and silicon-bonded hydrolysable groups-containing organosilane or a composition thereof or is an organic functional group-free and silanol group-containing cured organopolysiloxane layer produced by a condensation reaction-crosslinking of (b-2) a organic functional group-free and silicon-bonded hydrolysable groups-containing organopolysiloxane or a composition thereof,
   (c) a hydrosilyl group-containing cured organopolysiloxane layer free from the organic functional group is an organic functional group-free and residual hydrosilyl group-containing cured organopolysiloxane layer produced by a hydrolsilyaltion reaction-crosslinking of (c-1) a organic functional group-free hydrolsilyaltion reaction-curable organopolysiloxane composition.
[2] The cured organopolysiloxane resin film having gas barrier properties according to [1], wherein the organic functional group is an oxygen-containing organic functional group, the polymerizable organic functional group is a polymerizable oxygen-containing organic functional group, and the organic group is an oxygen-containing organic group.
[3] The cured organopolysiloxane resin film having gas barrier properties according to [2], wherein the oxygen-containing organic functional group is an acryloxy functional group, epoxy functional group, or oxetanyl functional group, the polymerizable organic functional group is an acryloxy functional group, epoxy functional group, oxetanyl functional group or alkenyether functional group, and the oxygen-containing organic group has a carbonyl group or C—O—C linkage.
[4] The cured organopolysiloxane resin film having gas barrier properties according to [3], wherein the acryloxy functional group is an acryloxyalkyl group or methacryloxyalkyl group and the epoxy functional group is a glycidoxyalkyl group or epoxycyclohexylalkyl group.
[5] The cured organopolysiloxane resin film having gas barrier properties according to [1], wherein the fiber reinforcement in the fiber-reinforced film comprises an inorganic fiber or synthetic fiber.
[6] The cured organopolysiloxane resin film having gas barrier properties according to [1] or [5], wherein the fiber reinforcement is in the form of a single fiber, yarn, woven cloth or non-woven cloth.”

This object is achieved by
“[7] A method of producing the cured organopolysiloxane resin film having gas barrier properties according to [1], comprising
   (I) forming a cured organopolysiloxane layer selected from the group consisting of
   (a) an organic functional group-containing cured organopolysiloxane layer,
   (b) a silanol group-containing cured organopolysiloxane layer free from the organic functional group,
   (c) a hydrosilyl group-containing cured organopolysiloxane layer free from the organic functional group,
   (d) a layer of cured organopolysiloxane having organic groups produced by polymerization between polymerizable organic functional groups of an organopolysiloxane having two or more polymerizable organic functional groups in one molecule, and
   (e) a cured organopolysiloxane layer formed by polymerizing the polymerizable organic functional groups with each other and reacting the crosslinking groups with each other of a polymerizable organic functional group- and crosslinking group-containing curable organopolysiloxane,
   by coating, on a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst; and then
(II) forming a transparent inorganic layer selected from the group consisting of a silicon oxynitride layer, silicon nitride layer, and silicon oxide layer, by vapor deposition, on the aforementioned cured organopolysiloxane layer.
[8] The method of producing a cured organopolysiloxane resin film having gas barrier properties according to [7], wherein the cured organopolysiloxane layer (a), the cured organopolysiloxane layer (b) and the cured organopolysiloxane layer (c) are formed by a condensation reaction or hydrosilylation reaction, the cured organopolysiloxane layer (d) is formed by polymerization between polymerizable organic functional groups by means of high energy ray irradiation or actinic energy ray irradiation or heating, and the cured organopolysiloxane layer (e) is formed by a condensation reaction or hydrosilylation reaction and by polymerization between polymerizable organic functional groups by means of high energy ray irradiation or actinic energy ray irradiation or heating.”

This object is achieved by
“[9] A cured organopolysiloxane resin film having gas barrier properties comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a silicon oxynitride layer that is formed on the fiber-reinforced film,
wherein a molar ratio of hydrosilyl groups of component (B) to unsaturated aliphatic hydrocarbyls of component (A) is within the range of 1.05 to 1.50, and the aforementioned cured organopolysiloxane resin has hydrosilyl groups.
[10] A method of producing the cured organopolysiloxane resin film having gas barrier properties according to [9], comprising forming a silicon oxynitride layer, by reactive ion plating, on a fiber-reinforced film made of a hydrosilyl group-containing cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst.”

This object is achieved by
“[11] A cured organopolysiloxane resin film having gas barrier properties comprising a fiber-reinforced film made of a cured organopolysiloxane resin which is transparent in the visible region and obtained by a crosslinking reaction between
   (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane,
is interposed between the aforementioned fiber-reinforced film and the aforementioned transparent inorganic layer,
a cured polymer layer is formed on the aforementioned transparent inorganic layer, and a transparent inorganic layer selected from the group consisting of a silicon oxynitride layer, silicon nitride layer, and silicon oxide layer is formed on the aforementioned cured polymer layer.
[12] A cured organopolysiloxane resin film having gas barrier properties according to [11], wherein the cured polymer is a ultraviolet ray-cured polymer, electron beam-cured polymer, or heat-cured polymer, and the fiber reinforcement in the fiber-reinforced film comprises an inorganic fiber or synthetic fiber, and is in the form of a single fiber, thread, woven cloth or non-woven cloth.

This object is achieved by
“[13] A method of producing the cured organopolysiloxane resin film having gas barrier properties according to [11], comprising
   (I) forming a cured organopolysiloxane layer selected from the group consisting of
   (a) an organic functional group-containing cured organopolysiloxane layer,
   (b) a silanol group-containing cured organopolysiloxane layer free from the organic functional group,
   (c) a hydrosilyl group-containing cured organopolysiloxane layer free from the organic functional group,
   (d) a layer of cured organopolysiloxane having organic groups produced by polymerization between polymerizable organic functional groups of an organopolysiloxane having two or more polymerizable organic functional groups in one molecule, and
   (e) a cured organopolysiloxane layer formed by polymerizing the polymerizable organic functional groups with each other and reacting the crosslinking groups with each other of a polymerizable organic functional group- and crosslinking group-containing curable organopolysiloxane, by coating, on a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst;
(II) forming a transparent inorganic layer selected from the group consisting of a silicon oxynitride layer, silicon nitride layer, and silicon oxide layer, by vapor deposition, on the aforementioned cured organopolysiloxane layer;
(III) forming a cured polymer layer, by coating, on the transparent inorganic layer; and then
(IV) forming a transparent inorganic layer selected from the group consisting of a silicon oxynitride layer, silicon nitride layer, and silicon oxide layer, by vapor deposition, on the aforementioned cured polymer layer.
[14] The method of producing a cured organopolysiloxane resin film having gas barrier properties according to claim 13, wherein the cured organopolysiloxane layer (a), the cured organopolysiloxane layer (b), and the cured organopolysiloxane layer (c) is formed by a condensation reaction or hydrosilylation reaction, the cured organopolysiloxane layer (d) is formed by polymerization between polymerizable organic functional groups by means of high energy ray irradiation or actinic energy ray irradiation or heating, the cured organopolysiloxane layer (e) is formed by a condensation reaction or hydrosilylation reaction and by polymerization between polymerizable organic functional groups by means of high energy ray irradiation or actinic energy ray irradiation or heating, and the cured polymer layer is formed by irradiating ultraviolet ray on a ultraviolet ray-curable monomer, oligomer or polymer in the presence of a photopolymerization initiator, irradiating electron beam on an electron beam-curable monomer, oligomer or polymer, or heating a heat-curable monomer, oligomer or polymer.”

This object is achieved by
“[15] A cured organopolysiloxane resin film having gas barrier properties comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a silicon oxynitride layer that is formed on the fiber-reinforced film, wherein a molar ratio of hydrosilyl groups of component (B) to unsaturated aliphatic hydrocarbyls of component (A) is within the range of 1.05 to 1.50, and the cured organopolysiloxane resin has hydrosilyl groups, a cured polymer layer is formed on the aforementioned silicon oxynitride layer, and a silicon oxynitride layer is formed on the aforementioned cured polymer layer.
[16] A cured organopolysiloxane resin film having gas barrier properties according to [15], wherein the cured polymer is an ultraviolet ray-cured polymer, electron beam-cured polymer, or heat-cured polymer, the fiber reinforcement in the fiber-reinforced film comprises an inorganic fiber or synthetic fiber, and is in the form of a single fiber, thread, woven cloth or non-woven cloth.”

This object is achieved by
“[17] A method of producing the cured organopolysiloxane resin film having gas barrier properties according to [15], comprising
   (I) forming a silicon oxynitride layer, by reactive ion plating, on a fiber-reinforced film made of a hydrosilyl group-containing cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst,
(II) forming a cured polymer layer, by coating, on the aforementioned silicon oxynitride layer, and then
(III) forming a silicon oxynitride layer, by reactive ion plating, on the cured polymer layer.
[18] The method of producing a cured organopolysiloxane resin film having gas barrier properties according to [17], wherein the cured polymer layer is formed by irradiating ultraviolet ray on a ultraviolet ray-curable monomer, oligomer or polymer in the presence of a photopolymerization initiator, irradiating electron beam on an electron beam-curable monomer, oligomer or polymer, or heating a heat-curable monomer, oligomer or polymer.”

### Effects of the Invention

The cured organopolysiloxane resin film, particularly free-standing film having gas barrier properties claimed in claim 1 and claims depending from claim 1 in the present application has remarkably high gas barrier properties, specifically an excellent capability to block a variety of gases, such as air, steam, nitrogen gas, oxygen gas, carbon dioxide gas, argon gas, and so forth, and low coefficient of linear thermal expansion, high tensile strength, and high modulus, since a transparent inorganic layer selected from the group consisting of a silicon oxynitride layer, i.e., silicon oxynitride film, silicon nitride layer, i.e., silicon nitride film, and silicon oxide layer, i.e., silicon oxide film is uniformly formed on a fiber-reinforced film made of a cured organopolysiloxane resin which is transparent in the visible region through an interposing cured organopolysiloxane layer (a), (b), (c), (d), or (e), and said inorganic layer firmly adheres to said fiber-reinforced film.

The cured organopolysiloxane resin film, particularly free-standing film having gas barrier properties according to claim 9 in the present application has remarkably high gas barrier properties, specifically an excellent capability to block a variety of gases, such as air, steam, nitrogen gas, oxygen gas, carbon dioxide gas, argon gas, and so forth, and low coefficient of linear thermal expansion, high tensile strength, and high modulus, since a transparent silicon oxynitride layer, i.e., silicon oxynitride film is uniformly formed on a fiber-reinforced film made of a cured organopolysiloxane resin that has hydrosilyl groups, and said silicon oxynitride layer firmly adheres to said fiber-reinforced film.

The cured organopolysiloxane resin film, particularly free-standing film having gas barrier properties according to 11 and claims depending from claim 11 in the present application has remarkably higher gas barrier properties, specifically a more excellent capability to block a variety of gases, such as air, steam, nitrogen gas, oxygen gas, carbon dioxide gas, argon gas, and so forth, and low coefficient of linear thermal expansion, high tensile strength, and high modulus, since a transparent inorganic layer selected from the group consisting of a silicon oxynitride layer, i.e., silicon oxynitride film, silicon nitride layer, i.e., silicon nitride film, and silicon oxide layer, i.e., silicon oxide film is uniformly formed on a fiber-reinforced film made of a cured organopolysiloxane resin which is transparent in the visible region through an interposing cured organopolysiloxane layer (a), (b), (c), (d), or (e), said inorganic layer firmly adheres to said fiber-reinforced film, a cured polymer layer is formed on said transparent inorganic layer, and a transparent inorganic layer is formed on said cured polymer layer.

The cured organopolysiloxane resin film, particularly free-standing film having gas barrier properties according to claim 15 and claims depending from claim 15 in the present application has remarkably higher gas barrier properties, specifically a more excellent capability to block a variety of gases, such as air, steam, nitrogen gas, oxygen gas, carbon dioxide gas, argon gas, and so forth, and low coefficient of linear thermal expansion, since a transparent silicon oxynitride layer, i.e., silicon oxynitride film is uniformly formed on a fiber-reinforced film made of a cured organopolysiloxane resin that has hydrosilyl groups, said silicon oxynitride layer firmly adheres to said fiber-reinforced film, a cured polymer layer is formed on said transparent silicon oxynitride layer, and a transparent silicon oxynitride layer is formed on said cured polymer layer.

The methods of producing the cured organopolysiloxane resin film, particularly free-standing film having gas barrier properties according to claim 7, claim 10, claim 13, claim 17, and claims depending from these claims in the present application provide the aforementioned cured organopolysiloxane resin film, particularly free-standing film having gas barrier properties easily and surely.

### BRIEF DESCRIPTION OF THE DRAWING

FIG. 1 is a cross-sectional diagram of a glass fiber-reinforced film made of a cured organopolysiloxane resin having gas barrier properties in which an organic functional group-containing cured organopolysiloxane layer is formed on a glass fiber-reinforced film made of a cured organopolysiloxane resin and a silicon oxynitride layer is formed on the glass fiber-reinforced film.

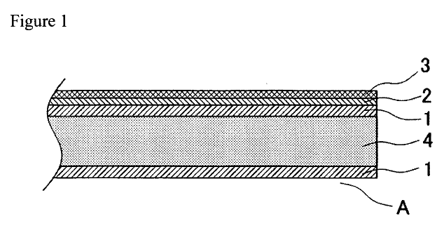

### MODE FOR CARRYING OUT THE INVENTION

A cured organopolysiloxane resin film, in particular free-standing film having gas barrier properties according to claim 1 of the first invention in the present application is characterized by comprising a fiber-reinforced film made of a cured organopolysiloxane resin which is transparent in the visible region and obtained by a crosslinking reaction between

(A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is interposed between the aforementioned fiber-reinforced film and the aforementioned transparent inorganic layer.
The cured organopolysiloxane resin film having gas barrier properties according to claim 1 can be expressed as follows:
A cured organopolysiloxane resin film having gas barrier properties characterized in that
a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is formed on a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst,
and a transparent inorganic layer selected from the group consisting of a silicon oxynitride layer, silicon nitride layer, and silicon oxide layer is formed on the aforementioned cured organopolysiloxane layer.

The fiber-reinforced film made of a visible region-transparent cured organopolysiloxane resin yielded by a crosslinking reaction between component (A) and component (B) in the presence of component (C) is in particular a free-standing film. This is a film that exists in a free-standing state and is not a film coated on a substrate such as a glass substrate, metal substrate, or ceramic substrate. The formation of the transparent inorganic layer selected from the group consisting of a silicon oxynitride layer, silicon nitride layer, and silicon oxide layer is superfluous when the cured organopolysiloxane resin film layer is formed on a gas barrier material such as glass, metal, or ceramic.

Under the action of component (C), component (A) undergoes crosslinking and curing through an addition reaction between its unsaturated aliphatic hydrocarbyl and the silicon-bonded hydrogen atom, that is, hydrosilyl group in component (B).

R in average siloxane unit formula (1) is a C₁ to C₁₀ monovalent hydrocarbyl and is bonded to the silicon atom in the organopolysiloxane. This C₁ to C₁₀ monovalent hydrocarbyl can be exemplified by alkyl such as methyl, ethyl, n-propyl, isopropyl, n-butyl, isobutyl, sec-butyl, tert-butyl, hexyl, octyl, and so forth; aryl such as phenyl, tolyl, xylyl, and so forth; aralkyl such as benzyl, phenylethyl, and so forth; and C₂ to C₁₀ unsaturated aliphatic hydrocarbyl such as vinyl, 1-propenyl, allyl, isopropenyl, 1-butenyl, 2-butenyl, 1-hexenyl, and so forth, and is particularly exemplified by alkenyl.

An average of at least 1.2 C₂ to C₁₀ unsaturated aliphatic hydrocarbyls are present per molecule in component (A). Viewed from the perspective of curability, preferably an average of at least 1.5 and more preferably an average of at least 2.0 C₂ to C₁₀ unsaturated aliphatic hydrocarbyls are present per molecule.

When component (B) is an organosilicon compound that contains two silicon-bonded hydrogen atoms per molecule, component (A) must contain a molecule that has at least three C₂ to C₁₀ unsaturated aliphatic hydrocarbyls per molecule in order for it to cure by the addition reaction with component (B).

When component (A) contains two C₂ to C₁₀ unsaturated aliphatic hydrocarbyls per molecule, component (B) must contain a molecule that has at least three silicon-bonded hydrogen atoms per molecule in order for component (A) to cure by the addition reaction with component (B).

While component (A) must be mainly organopolysiloxane resin that contains at least three C₂ to C₁₀ unsaturated aliphatic hydrocarbyls per molecule or organopolysiloxane resin that contains at least two C₂ to C₁₀ unsaturated aliphatic hydrocarbyls per molecule, component (A) may contain organopolysiloxane resin that contains one C₂ to C₁₀ unsaturated aliphatic hydrocarbyl per molecule.

a in the average siloxane unit formula (1) is a number with an average value in the range of 0.5<a<2. a denotes the average number of R's per silicon atom in the organopolysiloxane resin. When the average a=2 in the average siloxane unit formula (1), the organopolysiloxane is a diorganopolysiloxane, and, because this is straight chain or cyclic, a is smaller than an average of 2. The degree of branching in the organopolysiloxane resin molecule increases as a declines from an average of 2; however, a is preferably less than or equal to an average of 1.7 in order to fall into the organopolysiloxane resin category. a is greater than an average of 0.5; however, it is preferably greater than or equal to an average of 1.0 due to the substantial inorganic character at less than an average of 1.

Viewed from the perspective of the properties of the cured product, the organopolysiloxane resin represented by the average siloxane unit formula (1) is preferably composed of at least one siloxane unit represented by formula [X_{(3-b)}R¹_{b}SiO_{1/2}] (in the formula, X is a C₂ to C₁₀ monovalent unsaturated aliphatic hydrocarbyl, R¹ is a C₁ to C₁₀ monovalent hydrocarbyl other than X, and b is 0, 1, or 2) and at least one siloxane unit represented by formula [R²SiO_{3/2}] (in the formula, R² is a C₁ to C₁₀ monovalent hydrocarbyl other than X), or at least one siloxane unit represented by formula [X_{(3-b)}R¹_{b}SiO_{1/2}] (in the formula, X is C₂ to C₁₀ monovalent unsaturated aliphatic hydrocarbyl, R¹ is a C₁ to C₁₀ monovalent hydrocarbyl other than X, and b is 0, 1, or 2), at least one siloxane unit represented by formula [R²SiO_{3/2}] (in the formula, R² is a C₁ to C₁₀ monovalent hydrocarbyl other than X), and at least one siloxane unit represented by formula [SiO_{4/2}].

Viewed from the perspective of characteristics of the cured product and particularly the heat resistance, the organopolysiloxane resin represented by the average siloxane unit formula (1) is preferably represented by the average siloxane unit formula

[X_{(3-b)}R¹_{b}SiO_{1/2}]ᵥ[R²SiO_{3/2}]_{w} (2)

(in the formula, X, R¹, R², and b are defined as above, 0.80≦w<1.0, and v+w=1) or by the average siloxane unit formula

[X_{(3-b)}R¹_{b}SiO_{1/2}]ₓ[R²SiO_{3/2}]_{y}[SiO_{4/2}]_{z} (3)

(in the formula, X, R¹, R², and b are defined as above, 0<x<0.4, 0.5<y<1, 0<z<0.4, and x+y+z=1). Two or more of these organopolysiloxane resins may be used in combination.

X is a C₂ to C₁₀ monovalent unsaturated aliphatic hydrocarbyl group, and examples thereof are alkenyl groups such as vinyl, 1-propenyl, allyl, isopropenyl, 1-butenyl, 2-butenyl, 1-hexenyl, and so forth; vinyl is preferred based on considerations of the ease of production and the hydrosilylation reactivity.

R¹ and R² are C₁ to C₁₀ monovalent hydrocarbyl groups other than X and are the R groups defined above from which X is excluded. R¹ and R² can be exemplified by alkyl such as methyl, ethyl, n-propyl, isopropyl, n-butyl, isobutyl, sec-butyl, tert-butyl, hexyl, octyl, and so forth; aryl such as phenyl, tolyl, xylyl, and so forth; and aralkyl such as benzyl, phenylethyl, and so forth; wherein methyl and phenyl are preferred from the perspective of the heat resistance and ease of production of the organopolysiloxane resin. At least 50 mole % of the total monovalent hydrocarbyls in the molecule is preferably phenyl based on a consideration of thermal properties of the cured organopolysiloxane resin.

The [X_{(3-b)}R¹_{b}SiO_{1/2}] unit in the average siloxane unit formula (2) and the average siloxane unit formula (3) is exemplified by Me₂ViSiO_{1/2}, MePhViSiO_{1/2}, and MeVi₂SiO_{1/2}, and the R²SiO_{3/2} unit in the average siloxane unit formula (2) and the average siloxane unit formula (3) is exemplified by MeSiO_{3/2} and PhSiO_{3/2} wherein Me is methyl group; Ph is phenyl group, and Vi is vinyl group; this also applies hereafter.

The organopolysiloxane resin represented by the average siloxane unit formula (1) can additionally contain R₂SiO_{2/2} unit, wherein this R₂SiO_{2/2} unit is exemplified by Me₂SiO_{2/2}, MeViSiO_{2/2}, and MePhSiO_{2/2}.

The organosilicon compound having at least two silicon-bonded hydrogen atoms per molecule that is component (B) brings about crosslinking and curing through its addition reaction, under the action of component (C), with the silicon-bonded unsaturated aliphatic hydrocarbyls, particularly alkenyls in component (A).

Component (B) may be any of silylated hydrocarbon, organosilane, organosiloxane oligomer, organopolysiloxane, and so forth. In each instance these contain at least two silicon-bonded hydrogen atoms per molecule, while the organosiloxane oligomer and organopolysiloxane preferably contain an average of at least two silicon-bonded hydrogen atoms per molecule.

The molecular structure here is not particularly limited; however, in order to produce a high-strength cured product, at least 5 mole % of the total silicon-bonded groups is aromatic hydrocarbyl and more preferably at least 10 mole % is aromatic hydrocarbyl. Physical properties and thermal characteristics of the cured product are unsatisfactory at less than 5 mole %.

Phenyl, tolyl, and xylyl are examples of the monovalent aromatic hydrocarbyl wherein phenyl is preferred. The aromatic hydrocarbyl may be a divalent aromatic hydrocarbyl, for example, phenylene. The alkyl described above is preferred for the organic groups other than the monovalent aromatic hydrocarbyl, wherein methyl is more preferred.

Component (B) is specifically exemplified by the following: a silylated hydrocarbon and organosilane containing two silicon-bonded hydrogen atoms, e.g., diphenyldihydrogensilane, 1,3-bis(dimethylhydrogensilyl)benzene, 1,4-bis(dimethylhydrogensilyl)benzene, and so forth; organosiloxane oligomers as represented by the formulas (HMePhSi)₂O, (HMe₂SiO)₂SiPh₂, (HMePhSiO)₂SiPh₂, (HMe₂SiO)₂SiMePh, (HMe₂SiO)(SiPh₂)(OSiMe₂H), (HMe₂SiO)₃SiPh, and (HMePhSiO)₃SiPh; organopolysiloxane resin comprising (PhSiO_{3/2}) units and (Me₂HSiO_{1/2}) units; organopolysiloxane resin comprising (PhSiO_{3/2}) units, (Me₂SiO_{2/2}) units, and (Me₂HSiO_{1/2}) units; organopolysiloxane resin comprising (PhSiO_{3/2}) units, (MeSiO_{3/2}) units, and (MeHSiO_{1/2}) units; organopolysiloxane resin comprising (PhSiO_{3/2}) units and (MeHSiO_{2/2}) units; and organopolysiloxane comprising (Me₂HSiO_{1/2}) units, (MePh₂SiO_{1/2}) units, and (SiO_{4/2}) units.

Additional examples are a straight-chain organopolysiloxane comprising (MePhSiO_{2/2}) units and (Me₂HSiO_{1/2}) units; a straight-chain organopolysiloxane comprising (Me₂SiO_{2/2}) units, (MePhSiO_{2/2}) units, and (Me₂HSiO_{1/2}) units; a straight-chain organopolysiloxane comprising (MePhSiO_{2/2}) units, (MeHSiO_{2/2}) units, and (Me₃SiO_{1/2}) units; a straight-chain organopolysiloxane comprising (MePhSiO_{2/2}) units, (MeHSiO_{2/2}) units, and (Me₂HSiO_{1/2}) units; a straight-chain organopolysiloxane comprising (PhHSiO_{2/2}) units and (Me₃SiO_{1/2}) units; a straight-chain organopolysiloxane comprising (MeHSiO_{2/2}) units and (MePh₂SiO_{1/2}) units; and a cyclic organopolysiloxane comprising only (PhHSiO_{2/2}) units.

Two or more of these organosilicon compounds may be used in combination. Methods for the production of these organosilicon compounds are already publicly known or are commonly known in the art. For example, production can be carried out by the hydrolysis and condensation reaction of SiH-containing organochlorosilane alone or by the cohydrolysis and condensation reaction of SiH-containing organochlorosilane and SiH-free organochlorosilane.

The hydrosilylation reaction catalyst that is component (C) is preferably a metal from Group 8 of the Periodic Table or a compound of such a metal, among which platinum and platinum compounds are preferred. Examples here are microparticulate platinum, chloroplatinic acid, platinum/diolefin complexes, platinum/ketone complexes, platinum/divinyltetramethyldisiloxane complexes, and platinum/phosphine complexes. The hydrosilylation reaction catalyst content is preferably in the range of 0.05 ppm to 300 ppm and more preferably in the range of 0.1 ppm to 50 ppm, in each case as the weight of the metal with reference to the total weight of components (A) and (B). The crosslinking reaction does not develop adequately at below this range, while exceeding this range is not only pointless, but the optical properties may be impaired by the residual metal.

In order to inhibit the hydrosilylation and crosslinking reactions at ambient temperature and thereby lengthen working times, a hydrosilylation reaction retarder is preferably incorporated in addition to the aforementioned components (A), (B), and (C). Specific examples in this regard are 2-methyl-3-butyn-2-ol, 3,5-dimethyl-1-hexyn-3-ol, 1-ethynyl-1-cyclohexanol, phenylbutynol, and other alkinyl alcohols; 3-methyl-3-penten-1-yne, 3,5-dimethyl-3-hexene-1-yne, and other ene-yne compound; methyl(tris(1,1-dimethyl-2-propinyloxy)) silane, dimethyl(bis(1,1-dimethyl-2-propinyloxy)) silane, and other alkinylsilanes; dimethyl maleate, diethyl fumarate, bis(2-methoxy-1-methylethyl) maleate, and other unsaturated carboxylic acid esters; N,N,N′,N′-tetramethylethylenediamine, ethylenediamine, and other organic amine compounds; diphenylphosphine, diphenylphosphite, trioctylphosphine, diethylphenylphosphonite, and methyldiphenylphosphinite, and other organic phosphine compounds or organic phosphinite compounds. The hydrosilylation reaction retarder content is preferably an amount such that inhibits the hydrosilylation reaction between component (A) and component (B) at ambient temperature and not to inhibit the hydrosilylation reaction between component (A) and component (B) at elevated temperatures, concretely speaking, preferably an amount such that provides a value of 1 to 10,000 for the weight ratio versus the aforementioned hydrosilylation reaction catalyst.

In order to impart desired properties to the fiber-reinforced film comprising the cured organopolysiloxane resin and particularly the fiber-reinforced free-standing film comprising the cured organopolysiloxane resin, the hydrosilylation reaction-curable organopolysiloxane resin composition comprising components (A), (B), and (C) may incorporate, in addition to the essential components cited above and insofar as the object of the present invention is not impaired, the various additives typically incorporated into hydrosilylation reaction-curable organopolysiloxane resin compositions. For example, when a high optical transparency is not required of the fiber-reinforced film comprising the cured organopolysiloxane resin and particularly the fiber-reinforced free-standing film comprising the cured organopolysiloxane resin, inorganic micropowder that is a typical filler, for example, a reinforcing silica filler exemplified by fumed silica and colloidal silica, alumina, and so forth, may be incorporated in order thereby to increase the strength of the fiber-reinforced film comprising the cured organopolysiloxane resin and particularly the fiber-reinforced free-standing film comprising the cured organopolysiloxane resin. The inorganic powder content will vary with the purpose and the service and can be determined by simple blending tests.

Moreover, even when an inorganic powder is incorporated, the transparency of the fiber-reinforced film made of a cured organopolysiloxane resin can be preserved by adjusting the particle size of the powder. Since opacification due to particle addition is caused by the light scattering induced by the added particles, scattering can be prevented and the transparency of the fiber-reinforced film made of a cured organopolysiloxane resin can thereby be preserved when the particle diameter is no more than roughly one-fifth to one-sixth the wavelength of the incident light (corresponding to 80 to 60 nm for the visible region), although this also varies with the refractive index of the material making up the particles. Secondary aggregation of the particles is also a major factor in causing light scattering, and particles that have been subjected to a surface treatment may therefore be incorporated in order to inhibit secondary aggregation.

The hydrosilylation reaction-curable organopolysiloxane resin composition used to produce the fiber-reinforced film, particularly fiber-reinforced free-standing film made of a cured organopolysiloxan of the first invention in the present application may also incorporate a dye or pigment, e.g., a phthalocyanine-type dye, a fluorescent dye, a fluorescent pigment, and so forth. In particular, since the fiber-reinforced film, particularly fiber-reinforced free-standing film made of a cured organopolysiloxane of the present invention does not exhibit a specific absorption band in the visible region, functionalization then becomes possible through the incorporation of an additive that manifests a prescribed functionality by means of photoexcitation through the absorption of visible light.

When components (A), (B), and (C) are mixed, the hydrosilylation reaction can proceed even at ambient temperature, resulting in gelation and crosslinking and curing, and for this reason the suitable incorporation of a hydrosilylation reaction retarder as described above is preferred. When component (A) or component (B) is not a liquid at ambient temperature or is a liquid but a high viscosity liquid, dissolution in a suitable organic solvent is preferably done in advance. This organic solvent should have a boiling point no greater than 200° C. given that the temperature during crosslinking can also reach about 200° C., and should dissolve the component (A) or (B) and should not inhibit the hydrosilylation reaction, but is not otherwise particularly limited.

Examples of preferred organic solvents are ketones such as acetone, methyl isobutyl ketone, and so forth; aromatic hydrocarbons such as toluene, xylene, and so forth; aliphatic hydrocarbons such as heptane, hexane, octane, and so forth; halogenated hydrocarbons such as dichloromethane, chloroform, methylene chloride, 1,1,1-trichloroethane, and so forth; ethers such as THF and so forth; as well as dimethylformamide and N-methylpyrrolidone. The use amount for the organic solvent is, for example, in the range of 1 weight part to 300 weight parts per 100 weight parts of the total of components (A), (B), and (C), but is not limited to this range.

A fiber-reinforced film, particularly fiber-reinforced free-standing film made of a cured organopolysiloxane resin which is transparent in the visible region can be produced by mixing a hydrosilylation reaction-curable organopolysiloxane resin composition and staple fibers to homogeneity and curing the composition in a film state, or by impregnating a sheet-like fiber reinforcement with a hydrosilylation reaction-curable organopolysiloxane resin composition and curing the impregnated composition.

For manufacturing a fiber-reinforced film, particularly fiber-reinforced free-standing film made of a cured organopolysiloxane resin which is transparent in the visible region, a hydrosilylation reaction-curable organopolysiloxane resin composition is first produced by mixing components (A), (B), and (C), or components (A), (B), (C) and a hydrosilylation reaction retarder, or mixing these components and an organic solvent. Viewed from the perspective of coatability, the viscosity of the mixture or the solution here is preferably no greater than 1×10³ Pa·s and more preferably is no greater than 1×10² Pa·s.

Then a fiber reinforcement is impregnated in the aforementioned mixture or the solution, and the impregnated fiber reinforcement is heated at a sufficient temperature to cure the hydrosilylation reaction-curable organopolysiloxane resin composition.

The fiber-reinforced film made of a cured organopolysiloxane resin incorporates or includes a fiber reinforcement in the cured organopolysiloxane resin film. The fiber reinforcement incorporated in a film made of the cured organopolysiloxane resin resulting from the hydrosilylation reaction of component (A) and component (B) can lower coefficient of thermal expansion, and raise elastic properties and mechanical strength of the cured organopolysiloxane resin film. The fiber-reinforced film can be called a film reinforced with a fiber.

The fiber reinforcement can be any reinforcement comprising fibers, provided the reinforcement has a high modulus and high tensile strength. The fiber reinforcement typically has a Young's modulus at 25° C. of at least 3 GPa. For example, the reinforcement typically has a Young's modulus at 25° C. of from 3 to 1,000 GPa, alternatively from 3 to 200 GPa, alternatively from 10 to 100 GPa. Moreover, the reinforcement typically has a tensile strength at 25° C. of at least 50 MPa. For example, the reinforcement typically has a tensile strength at 25° C. of from 50 to 10,000 MPa, alternatively from 50 to 1,000 MPa, alternatively from 50 to 500 MPa.

An individual fiber which is the fiber reinforcement itself and an individual fiber constituting the reinforcement such as a woven fabric, has typically a circular cross-sectional shape, and has a diameter of from 1 to 100 μm, alternatively from 1 to 20 μm, alternatively form 1 to 10 μm. The individual fiber may be a filament or staple. The filament is continuous, meaning the fibers extend throughout the cured organopolysiloxane resin film in a generally unbroken manner, or chopped. The staple is shortly chopped many filaments.

The fiber reinforcement is typically heat-treated, washed with water or an organic solvent to remove organic contaminants prior to be impregnated with a hydrosilylation reaction-curable organopolysiloxane resin composition. For example, the fiber reinforcement is typically heated in air at an elevated temperature sufficient to remove impurities without melting it, for example, 575° C., for a suitable period of time, for example 2 hours.

Examples of fibers constituting the fiber reinforcements include, but are not limited to glass fibers, quartz fibers, silicon carbide fibers, graphite fibers; Nylon® fibers, polyester fibers such as polyethyleneterephtalate fibers, aromatic polyamide fibers such as Kevlar® and Nomex® which are products of E. I. duPont de Nemours and Co., acrylic fibers, polypropylene fibers.

Inorganic fibers and heat-stable synthetic fibers such as aromatic polyamide fibers and polyimide fibers from the standpoint of heat stability, and glass fibers, silica fibers, and quartz fibers are preferable from the standpoint of transparency of a fiber-reinforced film made of a cured organopolysiloxane resin.

Examples of glass fibers include fibers comprising an alkaline glass, a non-alkaline glass, low dielectric glass, high dielectric glass or e-glass. The fiber reinforcement comprising glass fibers is preferably sheet-like. Examples thereof include a woven cloth, knitted cloth, and nonwoven fabric.

A sheet-like glass cloth preferably comprises 50 to 800 monofilaments with the aforementioned fiber diameter and has a weight of 20 to 100 g/m².
The glass fiber can be pretreated with a silane coupling agent.

The fiber reinforcement can be impregnated in a hydrosilylation-curable organopolysiloxane resin composition using a variety of methods. For example, according to a first method, the fiber reinforcement can be impregnated by (i) applying a hydrosilylation-curable organopolysiloxane resin composition to a release liner to form an organopolysiloxane resin composition film; (ii) embedding a fiber reinforcement in the film; (iii) degassing the embedded fiber reinforcement; and (iv) applying the hydrosilylation-curable organopolysiloxane resin composition to the degassed embedded fiber reinforcement to form an impregnated fiber reinforcement.

In step (i), a hydrosilylation-curable organopolysiloxane resin composition, described above, is applied to a release liner to form a organopolysiloxane resin composition film. The release liner can be any rigid or flexible material having a surface from which the fiber-reinforced film made of a cured organopolysiloxane resin can be removed without damage by delamination after the organopolysiloxane resin composition is cured, as described below. Examples of release liners include, but are not limited to, Nylon film, polyethyleneterephthalate film, polytetrafluoroethylene resin film, and polyimide film,

The hydrosilylation-curable organopolysiloxane resin composition can be applied to the release liner using conventional coating techniques, such as spin-coating, dipping, spraying, brushing, or screen-printing. The hydrosilylation-curable organopolysiloxane resin composition is applied in an amount sufficient to embed the fiber reinforcement in step (ii), below.

In step (ii), a fiber reinforcement is embedded in the hydrosilylation-curable organopolysiloxane resin composition. The fiber reinforcement can be embedded in the hydrosilylation-curable organopolysiloxane resin composition by simply placing the reinforcement on the hydrosilylation-curable organopolysiloxane resin composition and allowing the hydrosilylation-curable organopolysiloxane resin composition to saturate the fiber reinforcement.

In step (iii), the embedded fiber reinforcement is degassed. The fiber reinforcement embedded in the hydrosilylation-curable organopolysiloxane resin composition can be degassed by subjecting it to a vacuum at a temperature of from room temperature (about.23±2° C.) to 60° C. for a period of time sufficient to remove entrapped air in the embedded reinforcement. For example, the embedded fiber reinforcement can typically be degassed by subjecting it to a pressure of from 1,000 to 20,000 Pa for 5 to 60 min. at room temperature.

In step (iv), the hydrosilylation-curable organopolysiloxane resin composition is applied to the degassed embedded fiber reinforcement to form an impregnated fiber reinforcement as described above for step (i).

The first method can further comprise the steps of (v) degassing the impregnated fiber reinforcement; (vi) applying a second release liner to the degassed impregnated fiber reinforcement to form an assembly; and (vii) compressing the assembly comprising the first release liner, the fiber reinforcement impregnated with the hydrosilylation-curable organopolysiloxane resin composition, and the second release liner.

The assembly can be compressed to remove excess organopolysiloxane resin composition and/or entrapped air, and to reduce the thickness of the impregnated fiber reinforcement. The assembly can be compressed using conventional equipment such as a stainless steel roller, hydraulic press, rubber roller, or laminating roll set. The assembly is typically compressed at a pressure of from 1,000 Pa to 10 MPa and at a temperature of from room temperature (about.23±2° C.) to 50° C.

Alternatively, according to a second method, the fiber reinforcement can be impregnated in a hydrosilylation-curable organopolysiloxane resin composition by (i) depositing a fiber reinforcement on a first release liner; (ii) embedding the fiber reinforcement in a hydrosilylation-curable organopolysiloxane resin composition; (iii) degassing the embedded fiber reinforcement; and (iv) applying the organopolysiloxane resin composition to the degassed embedded fiber reinforcement to form an impregnated fiber reinforcement.

The second method can further comprise the steps of (v) degassing the impregnated fiber reinforcement; (vi) applying a second release liner to the degassed impregnated fiber reinforcement to form an assembly; and (vii) compressing the assembly consisting of the first release liner, the fiber reinforcement impregnated with the hydrosilylation-curable organopolysiloxane resin composition and the second release liner. In the second method, steps (iii) to (vii) are as described above for the first method of impregnating a fiber reinforcement in a hydrosilylation-curable organopolysiloxane resin composition.

In step (ii), the fiber reinforcement is embedded in a hydrosilylation-curable organopolysiloxane resin composition. The fiber reinforcement can be embedded in the organopolysiloxane resin composition by simply covering the fiber reinforcement with the composition and allowing the composition to saturate the fiber reinforcement.

Furthermore, when the fiber reinforcement is a woven or nonwoven fabric, the fiber reinforcement can be impregnated in a hydrosilylation-curable organopolysiloxane resin composition by passing it through the composition. The fabric is typically passed through the organopolysiloxane resin composition at a rate of from 1 to 1,000 cm/s at room temperature (about 23±2° C.).

In the second step of the method of preparing a cured organopolysiloxane resin film incorporating the fiber reinforcement, i.e., a fiber-reinforced film made of a cured organopolysiloxane resin, the impregnated fiber reinforcement is heated at a temperature sufficient to cure the organopolysiloxane resin composition. The impregnated fiber reinforcement can be heated at atmospheric, subatmospheric, or supraatmospheric pressure. The impregnated fiber reinforcement is typically heated at a temperature of from room temperature (about 23±2° C.) to 250° C., alternatively from room temperature to 200° C., alternatively from room temperature to 150° C., at atmospheric pressure. The reinforcement is heated for a length of time sufficient to cure (cross-link) the organopolysiloxane resin composition. For example, the impregnated fiber reinforcement is typically heated at a temperature of from 150 to 200° C. for a time of from 0.1 to 3 hours.

Alternatively, the impregnated fiber reinforcement can be heated in a vacuum at a temperature of from 100 to 200° C. and a pressure of from 1,000 to 20,000 Pa for a time of from 0.5 to 3 hours. The impregnated fiber reinforcement can be heated in a vacuum using a conventional vacuum bagging process. In a typically process, a bleeder (e.g., made of polyester) is applied over the impregnated fiber reinforcement, a breather (e.g., made of Nylon®, or polyester) is applied over the bleeder, a vacuum bagging film (e.g., made of Nylon®) equipped with a vacuum nozzle is applied over the breather, the assembly is sealed with tape, a vacuum (e.g., 1,000 Pa) is applied to the sealed assembly, and the evacuated bag is heated as described above.

A fiber-reinforced film made of a cured organopolysiloxane resin can be produced by coating a hydrosilylation reaction-curable organopolysiloxane resin composition on a plain rigid substrate in place of a release liner, curing the coated composition, and peeling the fiber-reinforced film away.

The cured organopolysiloxane resin film incorporating the fiber reinforcement, i.e., the fiber-reinforced film made of the cured organopolysiloxane resin typically comprises from 10 to 99% (w/w), alternatively from 30 to 95% (w/w), alternatively from 60 to 95% (w/w), alternatively from 80 to 95% (w/w), of the cured organopolysiloxane resin. Also, The fiber-reinforced film made of the cured organopolysiloxane resin typically has a thickness of from 15 to 500 μm, alternatively from 15 to 300 μm, alternatively from 20 to 150 μm, alternatively from 30 to 125 μm.

The fiber-reinforced film made of the cured organopolysiloxane resin typically has a flexibility such that the film can be bent over a cylindrical steel mandrel having a diameter less than or equal to 3.2 mm without cracking, where the flexibility is determined as described in ASTM Standard D522-93a, Method B.

The fiber-reinforced film made of the cured organopolysiloxane resin has a low coefficient of linear thermal expansion (CTE), high tensile strength, and high modulus. For example the fiber-reinforced film typically has a CTE of from 0 to 80 μm/m° C., alternatively from 0 to 20 μm/m° C., alternatively from 2 to 10 μm/m° C. at temperature of from room temperature (about 23±2° C.) to 200° C. Also, the fiber-reinforced film typically has a tensile strength at 25° C. of from 50 to 200 MPa, alternatively from 80 to 200 MPa, alternatively from 100 to 200 MPa. Further, the fiber-reinforced film typically has a Young's modulus at 25° C. of from 2 to 10 GPa, alternatively from 2 to 6 GPa, alternatively from 3 to 5 GPa.

The fiber-reinforced film made of the cured organopolysiloxane resin is preferably transparent in the visible region.

The transparency of the fiber-reinforced film made of the cured organopolysiloxane resin depends on a number of factors, such as the refractive index of the cured organopolysiloxane resin, the thickness of the film, and the refractive index of the fiber reinforcement. The fiber-reinforced film made of the cured organopolysiloxane resin typically has a transparency (% transmittance) of at least 50%, alternatively at least 60%, alternatively at least 75%, alternatively at least 85%, in the visible region of the electromagnetic spectrum.

The fiber-reinforced film made of the cured organopolysiloxane resin produced in this manner is a free-standing film. It is not a film coated on a substrate, such as a glass, metal, or ceramic substrate, and exists in a free-standing or independent state. Free-standing films are also known as self-supporting films and unsupported films.

The cured organopolysiloxane resin in this fiber-reinforced film, particularly fiber-reinforced free-standing film made of the cured organopolysiloxane resin does not have a specific light absorption band in the visible region and have a light transmittance of at least 85% at 400 nm and provide a light transmittance of at least 88% in the 500 to 700 nm wavelength range. Because this fiber-reinforced film, particularly fiber-reinforced free-standing film made of the cured organopolysiloxane resin is not produced by the application of stress to a melt, it is free of the problem of molecular chain orientation. Accordingly, the birefringence is so small that it can be neglected.

This cured organopolysiloxane resin incorporating the fiber-reinforcement is obtained by a hydrosilylation reaction-based crosslinking reaction between the unsaturated aliphatic hydrocarbyl groups in component (A) and the silicon-bonded hydrogen atoms in component (B). Because crosslinking by this hydrosilylation reaction is not accompanied by the evolution of low molecular weight by-products, the volumetric shrinkage of the film that accompanies crosslinking is held down to low levels in comparison to the condensation-type crosslinking reaction encountered in the usual thermosetting resins. As a consequence, there is also little internal stress in the film, particularly free-standing film made of the cured organopolysiloxane resin yielded by the hydrosilylation crosslinking reaction. The generation of internal stress-induced strain is therefore inhibited. This also desirably contributes to an improved optical uniformity of the film and an improved film strength.

Even when heated to 300° C., this inorganic fiber-reinforced film, particularly free-standing film made of the cured organopolysiloxane resin keeps their film shape and also does not exhibit weight change. Moreover, it also exhibits excellent mechanical properties after heating and exhibit almost no change in mechanical properties by the heating.

Accordingly, this inorganic fiber-reinforced film, particularly free-standing film made of the cured organopolysiloxane resin has the high heat resistance typical of general-purpose engineering plastics, such as polycarbonates, and as a consequence are well suited for application as a substrate or base for gas barrier films where exposure to high temperatures occurs during formation of a transparent inorganic layer.

The methylphenylvinylpolysiloxane resin which is a typical example of component (A) has a reflective index of from 1.41 to 1.54 at ambient temperature. The reflective index becomes larger as the methylphenylvinylpolysiloxane resin contains larger amount of phenyl groups. The glass fiber-reinforced film made of the cured methylphenylvinylpolysiloxane resin is transparent at ambient temperature, since the glass fiber has a reflective index of 1.53 at ambient temperature. But the transparency of the cured methylphenylvinylpolysiloxane resin declines as the temperature elevates, and the cured methylphenylvinylpolysiloxane resin becomes opaque at 65° C. The glass fiber-reinforced film made of the cured methylphenylvinylpolysiloxane resin is useful for using at ambient temperature.

A cured organopolysiloxane resin film having gas barrier properties of the first invention in the present application is characterized by comprising a fiber-reinforced film made of a cured organopolysiloxane resin which is transparent in the visible region and obtained by a crosslinking reaction between

(A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is interposed between the aforementioned fiber-reinforced film and the aforementioned transparent inorganic layer.

(a) An organic functional group-containing cured organopolysiloxane layer is selected from the group consisting of (a-1) an organic functional group-containing, silanol group- and hydrosilyl group-free cured organopolysiloxane layer, (a-2) an organic functional group- and silanol group-containing cured organopolysiloxane layer, and (a-3) an organic functional group- and hydrosilyl group-containing cured organopolysiloxane layer. But (a-4) an organic functional group-, silanol group-, and hydrosilyl group-containing cured organopolysiloxane layer can be possible.

(a-1) an organic functional group-containing, silanol group- and hydrosilyl group-free cured organopolysiloxane layer is an organic functional group-containing, silanol group- and residual hydrosilyl group-free cured organopolysiloxane layer produced by a hydrosilylation reaction-crosslinking of (a-1-1) a organic functional group-containing hydrosilylation reaction-curable organopolysiloxane composition.

(a-2) An organic functional group- and silanol group-containing cured organopolysiloxane layer is an organic functional group- and silanol group-containing cured organopolysiloxane layer produced by a condensation reaction-crosslinking of (a-2-1) an organic functional group- and silicon-bonded hydrolysable groups-containing curable organosilane per se or a composition thereof or an organic functional group- and silanol group-containing cured organopolysiloxane layer produced by a condensation reaction-crosslinking of (a-2-2) an organic functional group- and silicon-bonded hydrolysable groups-containing curable organopolysiloxane per se or a composition thereof.

(a-3) an organic functional group- and hydrosilyl group-containing cured organopolysiloxane layer is an organic functional group- and residual hydrosilyl group-containing cured organopolysiloxane layer produced by a hydrosilylation reaction-crosslinking of (a-3-1) an organic functional group-containing hydrosilylation reaction-curable organopolysiloxane composition.

A cured organopolysiloxane resin film having gas barrier properties of the first embodiment of the first invention in the present application is characterized by comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and a silicon oxide layer that is formed on the fiber-reinforced film, wherein
(a) an organic functional group-containing cured organopolysiloxane layer
is interposed between the aforementioned fiber-reinforced film and the aforementioned transparent inorganic layer.

The organic functional group bonds to the silicon atom in the organopolysiloxane constituting the cured organopolysiloxane layer.

Viewed from the standpoint of adhesion of the transparent inorganic layer selected from the group consisting of the silicon oxynitride layer, silicon nitride layer, and silicon oxide layer, the organic functional group is preferably an oxygen-containing organic functional group. The oxygen-containing organic functional group preferably consists of carbon atoms, hydrogen atoms and oxygen atoms, or consists of carbon atoms, hydrogen atoms, oxygen atoms and nitrogen atoms. The oxygen-containing organic group preferably contains a carbonyl group, or a polar bond, e.g., a carboxylic acid ester bond, carboxylic acid amide bond, ether bond (C—O—C) and so forth.

When the cured organopolysiloxane layer is formed by a hydrosilylation reaction, the organic functional group which does not inhibit the hydrosilylation reaction is preferable.

An acrylic functional group, an epoxy functional group, and an oxetanyl functional group are preferred examples of the organic functional group, specifically oxygen-containing organic functional group.

Other examples are a crotonyl functional group and a cinnamoyl functional group, which can be regarded as types of the acrylic functional group.

The acrylic functional group is known as an acryloyl functional group, and its representative example is represented by the formula CH₂═CHCO— and the formula CH₂ CH(CH₃)CO—.

Preferred acrylic functional groups can be exemplified by an acryloxy functional group and acrylamide functional group;

Preferred acryloxy functional groups can be exemplified by an acryloxyalkyl group represented by CH₂═CHCOOR³— (wherein R³ in the formulas is an alkylene group such as propylene) such as acryloxypropyl group, and by a methacryloxyalkyl group represented by CH₂═CH(CH₃)COOR³— (wherein R³ in the formulas is an alkylene group such as propylene) such as methacryloxypropyl group.
Preferred acrylamide functional groups can be exemplified by a N-alkyl-N-acrylamidealkyl group represented by CH₂═CHCON(R⁴)R³— (wherein R³ is an alkylene group such as propylene, and R⁴ is an alkyl group such as methyl) such as N-alkyl-N-acrylamidepropyl group, and by a N-alkyl-N-methacrylamide group represented by CH₂═C(CH₃)CON(R⁴)R³— (wherein R³ is an alkylene group such as propylene, and R⁴ is an alkyl group such as methyl) such as N-alkyl-N-methacrylamidepropyl group.
The alkylene group here preferably has 2 to 6 carbon atoms.

Preferred specific examples of the epoxy functional group are epoxymethyl group; 2-epoxyethyl group; glycidoxyalkyl groups such as β-1-glycidoxyethyl group and 3-glycidoxpropyl group; and epoxycyclohexylalkyl groups such as β-(3,4-epoxycyclohexyl)ethyl group and 3-(3,4-epoxycyclohexyl)propyl group. Preferred specific examples of the oxetanyl functional group are 2-oxetanylbutyl group and 3-(2-oxetanylbutyloxy)propyl group.

The aforementioned acrylic functional group can be polymerized by exposure to high-energy radiation or actinic energy radiation, e.g., ultraviolet radiation, electron beam, gamma radiation, and so forth, and it is therefore also a polymerizable organic functional group. Moreover, this acrylic functional group again falls into the category of polymerizable organic functional groups because it can be polymerized by the application of heat. The vinyl ether group, for example, the vinyloxyalkyl group is another organic functional group that exhibits polymerizability. Preferred specific examples of the alkenyl ether functional group are vinyloxyalkyl group, allyloxyalkyl group, and allyloxyphenyl group. This alkenyl has preferably 2 to 6 carbon atoms.

The aforesaid epoxy functional group can undergo ring-opening polymerization upon exposure to ultraviolet radiation in the presence of a photopolymerization initiator and is thus also a polymerizable organic functional group.

The epoxy functional group and the oxetanyl functional group are also polymerizable organic functional groups by virtue of undergoing ring-opening polymerization in the presence of a catalyst such as an aliphatic amine, alicyclic amine, aromatic amine, imidazole, organic dicarboxylic acid, organic dicarboxylic acid anhydride, and so forth.

Examples of other organic functional groups are hydroxyl-containing organic functional groups and oxyalkylene bond-containing organic functional groups.

The hydroxyl-containing organic functional groups are exemplified by hydroxyalkyl groups such as 3-hydroxypropyl. The oxyalkylene bond-containing organic functional groups are exemplified by an alkoxyalkyl group, and a hydroxypoly(alkyleneoxy)alkyl group such as hydroxy(ethyleneoxy)propyl and hydroxypoly(ethyleneoxy)propyl.

Amino-containing organic functional groups can also be used from the standpoint of the adhesiveness of the transparent inorganic layer selected from the group consisting of a silicon oxynitride layer, silicon nitride layer, and silicon oxide layer, and these organic functional groups can be exemplified by 3-aminopropyl, N-(β-aminoethyl)-3-aminopropyl, N-phenylaminopropyl, N-cyclohexylaminopropyl, and N-benzylaminopropyl.

The organic functional group-containing cured organopolysiloxane layer can be formed on a fiber-reinforced film, particularly fiber-reinforced free-standing film made of a cured organopolysiloxane resin by coating an organic functional group-containing curable organosilane per se or a composition thereof onto the film and curing said organosilane per se or a composition thereof.

The organic functional group-containing curable organosilane per se or composition thereof is preferably an organic functional group-containing, condensation reaction-curable organosilane per se or a composition thereof, that can cure by a condensation reaction between silicon-bonded condensation-reactive groups, for example, an alcohol-eliminating condensation reaction.

Formation can also be achieved by coating and curing an organic functional group-containing curable organopolysiloxane per se or a composition thereof.

The organic functional group-containing curable organopolysiloxane per se or composition thereof is preferably an organic functional group-containing, condensation reaction-curable organopolysiloxane per se or a composition thereof, that can cure by a condensation reaction, for example, an alcohol-eliminating condensation reaction between silicon-bonded hydrolyzable groups, for example, silicon-bonded alkoxy groups and silanol groups.

The organic functional group-containing curable organopolysiloxane composition is also preferably an organic functional group-containing, hydrosilylation reaction-curable organopolysiloxane composition that can cure by an addition reaction between silicon-bonded alkenyl groups and hydrosilyl groups.

The organic functional group-containing curable organopolysiloxane should contain at least one organic functional group per molecule, but preferably contains a plurality of organic functional groups per molecule from the standpoint of the adhesiveness of the transparent inorganic layer selected from the silicon oxynitride layer, silicon nitride layer, and silicon oxide layer. The organic functional group may be up to 100 mole % of the total organic groups that are bonded through the C—Si bond in the organic functional group-containing curable organopolysiloxane. For example, this value is 43.4 mole % in Synthesis Example 2 hereinafter described.

(1) An example of the organic functional group-containing, condensation reaction-curable organosilane is a humidity-curable organosilane that contains one organic functional group and three silicon-bonded hydrolyzable groups.

(2) Examples of the organic functional group-containing, condensation reaction-curable organosilane compositions are a curable composition comprising a condensation reaction catalyst and organosilane that contains one organic functional group and three silicon-bonded hydrolyzable groups, and a curable composition comprising a condensation reaction catalyst, organosilane that contains one organic functional group and two silicon-bonded hydrolyzable groups, and organosilane that contains three or four silicon-bonded hydrolyzable groups.

(3) An example of the organic functional group-containing, condensation reaction-curable organopolysiloxane is a humidity-curable organopolysiloxane that contains at least one organic functional group per molecule and at least three silicon-bonded hydrolyzable groups per molecule.

(4) Examples of the organic functional group-containing, condensation reaction-curable organopolysiloxane compositions are a curable composition comprising a condensation reaction catalyst and organopolysiloxane that contains at least one organic functional group per molecule and at least three silicon-bonded hydrolyzable groups per molecule, and a curable composition comprising a condensation reaction catalyst, organopolysiloxane that contains at least one organic functional group per molecule and one or two silicon-bonded hydrolyzable groups per molecule, and organopolysiloxane that contains at least three silicon-bonded hydrolyzable groups while lacking the organic functional group.

The organic functional group in the above-cited organic functional group-containing curable organosilane, organic functional group-containing, condensation reaction-curable organosilane composition, organic functional group-containing curable organopolysiloxane, organic functional group-containing, condensation reaction-curable organopolysiloxane, and organic functional group-containing, condensation reaction-curable organopolysiloxane composition is that which has already been described in paragraphs [0089] to [0094].

The condensation-reactive group in the organic functional group-containing, condensation reaction-curable organosilane and the organic functional group-containing, condensation reaction-curable organopolysiloxane is silanol group and a silicon-bonded hydrolyzable group, which can be exemplified by alkoxy, alkenyloxy, acyloxy, ketoxime, and alkylamino, wherein alkoxy is preferred and methoxy and ethoxy are more preferred considering the volatilization behavior of alcohols produced by hydrolysis thereof.

The auxiliary use of heating or an hydrolysis/condensation reaction catalyst is necessary in those instances where the silicon-bonded hydrolyzable group does not undergo humidity-induced hydrolysis/condensation or is not susceptible to hydrolysis/condensation. The hydrolysis/condensation reaction catalyst can be exemplified by tetraalkoxytitanium, alkoxytitanium chelates, tetraalkoxyzirconium, trialkoxyaluminum, organotin compounds exemplified by dialkyltin dicarboxylate salts and tin salts of a tetracarboxylic acid, and organic amines.

The aforementioned organic functional group-containing, condensation reaction-curable organosilane composition and organic functional group-containing, condensation reaction-curable organopolysiloxane composition may contain a microparticulate reinforcing silica insofar as the optical transmittance of the cured product is not impaired.

A typical example of the organosilane that contains one organic functional group per molecule and three silicon-bonded hydrolyzable groups per molecule is an organic functional group-containing organotrialkoxysilane represented by the formula YR⁵Si(OR⁶)₃ (in the formula, YR⁵ is an organic functional group, R⁵ is C₁ to C₆ alkylene, and R⁶ is C₁ to C₆ alkyl). The organic functional group here is the same as that described above. The C₁ to C₆ alkylene can be exemplified by ethylene, propylene, butylene, pentylene, and hexylene. R⁶ can be exemplified by methyl, ethyl, propyl, and butyl. C₁ to C₆ alkylene means alkylene group having one to six carbon atoms, and C₁ to C₆ alkyl means alkyl group having one to six carbon atoms.

The following are specific examples of the organic functional group-containing organotrialkoxysilane:
3-acryloxypropyltrimethoxysilane,
3-methacryloxypropyltrimethoxysilane,
3-methacryloxypropyltriethoxysilane,
3-glycidoxypropyltrimethoxysilane,
3-glycidoxypropyltriethoxysilane,
2-(3,4-epoxycyclohexyl)ethyltrimethoxysilane,
2-(3,4-epoxycyclohexyl)ethyltriethoxysilane,
3-hydroxypropyltriethoxysilane,
3-aminopropyltrimethoxysilane,
3-aminopropyltriethoxysilane,
3-phenylaminopropyltrimethoxysilane,
3-cyclohexylaminopropyltrimethoxysilane,
3-(2-aminoethylamino)propyltrimethoxysilane, and
3-benzylaminopropyltrimethoxysilane.

Typical examples of the organosilane that contains one organic functional group per molecule and one or two silicon-bonded hydrolyzable groups per molecule are an organic functional group-containing organodialkoxysilane represented by the formula YR⁵SiR⁷(OR⁶)₂ and an organic functional group-containing organomonoalkoxysilane represented by the formula YR⁵Si(R⁷)₂(OR⁶) (in the formulas, YR⁵ is an organic functional group, R⁵ is C₁ to C₆ alkylene, R⁶ is C₁ to C₆ alkyl, and R⁷ is C₁ to C₆ alkyl or phenyl group).

Specific examples thereof are as follows:
3-methacryloxypropylmethyldimethoxysilane,
3-methacryloxypropylmethyldiethoxysilane,
3-methacryloxypropyldimethylmethoxysilane,
3-glycidoxypropylmethyldimethoxysilane,
3-glycidoxypropylmethyldiethoxysilane,
3-glycidoxypropyldimethylmethoxysilane,
2-(3,4-epoxycyclohexyl)ethylmethyldimethoxysilane,
2-(3,4-epoxycyclohexyl)ethylmethyldiethoxysilane,
3-aminopropylmethyldimethoxysilane, and
3-(2-aminoethylamino)propylmethyldiethoxysilane.

A typical example of the organic functional group-free organosilane that contains three silicon-bonded hydrolyzable groups per molecule is a hydrophobic organotrialkoxysilane represented by the formula R⁸Si(OR⁶)₃ (in the formula, R⁸ is C₁ to C₆ alkyl, C₂ to C₆ alkenyl, or phenyl group, and R⁶ is C₁ to C₆ alkyl). C₂ to C₆ alkenyl means alkenyl group having two to six carbon atoms.

Specific examples are alkyltrialkoxysilanes exemplified by methyltrimethoxysilane, methyltriethoxysilane, methyltripropoxysilane, ethyltrimethoxysilane, and ethyltripropoxysilane, phenyltrialkoxysilanes exemplified by phenyltrimethoxysilane and phenyltriethoxysilane, and vinyltrialkoxysilanes exemplified by vinyltrimethoxysilane and vinyltriethoxysilane.

The organic functional group-free organosilane that contains four silicon-bonded hydrolyzable groups in each molecule is exemplified by tetraalkoxysilane such as tetraethoxysilane and tetrapropoxysilane.

The organopolysiloxane that contains at least one organic functional group per molecule and at least three silicon-bonded hydrolyzable groups per molecule can be exemplified by the partial hydrolysis and condensation product from an organic functional group-containing organotrialkoxysilane represented by the formula YR⁵Si(OR⁶)₃ (in the formula, YR⁵ is an organic functional group, R⁵ is C₁ to C₆ alkylene, and R⁶ is C₁ to C₆ alkyl) and by the partial condensation reaction product which retains four silicon-bonded alkoxy groups of the organic functional group-containing organotrialkoxysilane represented by the formula YR⁵Si(OR⁶)₃ and a silanol-endblocked dimethylpolysiloxane of which degree of polymerization is 2 to 50.

An example of the organopolysiloxane that has at least one organic functional group per molecule and one or two silicon-bonded hydrolyzable groups per molecule is the partial condensation reaction product retaining two silicon-bonded alkoxy groups of an organic functional group-containing organodialkoxysilane represented by the formula YR⁵SiR⁷(OR⁶)₂ (in the formula, YR⁵ is an organic functional group, R⁵ is C₁ to C₆ alkylene, R⁶ is C₁ to C₆ alkyl, and R⁷ is C₁ to C₆ alkyl or phenyl group) and a silanol-endblocked dimethylpolysiloxane of which degree of polymerization is 2 to 50.

Examples of the organic functional group-free organopolysiloxane that contains at least three silicon-bonded hydrolyzable groups per molecule are the partial hydrolysis and condensation product of a hydrophobic organotrialkoxysilane represented by the formula R⁸Si(OR⁶)₃ (in the formula, R⁸ is C₁ to C₆ alkyl, C₂ to C₆ alkenyl, or phenyl group, and R⁶ is C₁ to C₆ alkyl), and the partial condensation reaction product which retains four silicon-bonded alkoxy groups of a hydrophobic organotrialkoxysilane represented by the formula R⁸Si(OR⁶)₃ and a silanol-endblocked dimethylpolysiloxane of which degree of polymerization is 2 to 50.

The aforementioned organic functional group-containing, condensation reaction-curable organosilane per se or composition thereof, or the aforementioned organic functional group-containing, condensation reaction-curable organopolysiloxane per se or composition thereof, can be coated on the fiber-reinforced film made of a cured organopolysiloxane resin and can be cured by heating or by standing at ambient temperature. The auxiliary use of heating as described above or an hydrolysis/condensation reaction catalyst is necessary in those instances where humidity-induced hydrolysis/condensation does not occur or hydrolysis/condensation proceeds with difficulty.

The organic functional group-containing, hydrosilylation reaction-curable organopolysiloxane composition can be exemplified by the following:

(1) a composition comprising an organopolysiloxane that contains at least one organic functional group per molecule and at least two silicon-bonded alkenyl groups per molecule, an organosilane that lacks the organic functional group and that contains at least two silicon-bonded hydrogen atoms per molecule excluding, however, the combination of an organopolysiloxane that contains two silicon-bonded alkenyl groups with an organosilane that contains two silicon-bonded hydrogen atoms, and a hydrosilylation reaction catalyst, and

(2) a composition comprising an organopolysiloxane that contains at least one organic functional group per molecule and at least two silicon-bonded alkenyl groups per molecule, an organopolysiloxane that lacks the organic functional group and that contains at least two silicon-bonded hydrogen atoms per molecule (excluding, however, the combination of an organopolysiloxane that contains two silicon-bonded alkenyl groups with an organopolysiloxane that contains two silicon-bonded hydrogen atoms), and a hydrosilylation reaction catalyst.

Additional examples are as follows:

(3) a composition comprising an organopolysiloxane that lacks the organic functional group and that contains at least two silicon-bonded alkenyl groups per molecule, an organopolysiloxane that contains at least one organic functional group per molecule and at least two silicon-bonded hydrogen atoms per molecule (excluding, however, the combination of an organopolysiloxane that contains two silicon-bonded alkenyl groups with an organopolysiloxane that contains two silicon-bonded hydrogen atoms), and a hydrosilylation reaction catalyst, and

(4) a composition comprising an organopolysiloxane that contains at least one organic functional group per molecule and at least two silicon-bonded alkenyl groups per molecule, an organopolysiloxane that contains at least one organic functional group per molecule and at least two silicon-bonded hydrogen atoms per molecule (excluding, however, the combination of an organopolysiloxane that contains two silicon-bonded alkenyl groups with an organopolysiloxane that contains two silicon-bonded hydrogen atoms), and a hydrosilylation reaction catalyst.

The organic functional groups in the aforementioned organic functional group-containing organopolysiloxane and organic functional group-containing organosilane are as described in paragraphs [0089] to [0094].

The alkenyl in the aforementioned organopolysiloxanes can be exemplified by vinyl, allyl, butenyl, pentenyl, and hexenyl with vinyl being preferred.

Specific examples of the organopolysiloxane that contains at least one organic functional group per molecule and at least two silicon-bonded alkenyl groups per molecule are as follows:
dimethylsiloxane-methyl(3-methacryloxypropyl)siloxane copolymer endblocked at both terminals by dimethylvinylsiloxy groups,
dimethylsiloxane-methylvinylsiloxane copolymer endblocked at both terminals by dimethyl(3-methacryloxypropyl)siloxy groups,
dimethylsiloxane-methyl(3-glycidoxypropyl)siloxane copolymer endblocked at both terminals by dimethylvinylsiloxy groups,
dimethylsiloxane-methylvinylsiloxane copolymer endblocked at both terminals by dimethyl(3-glycidoxypropyl)siloxy groups,
(3-glycidoxypropyl)siloxane-dimethylsiloxane-methylvinylsiloxane copolymer,
3-methacryloxypropylsiloxane-dimethylsiloxane-methylvinylsiloxane copolymer,
3-methacryloxypropylsilsesquioxane-vinylsilsesquioxane copolymer,
3-glycidoxypropylsilsesquioxane-vinylsilsesquioxane copolymer, and

Specific examples of theorganopolysiloxane that lacks the organic functional group and that contains at least two silicon-bonded alkenyl groups per molecule are as follows:
dimethylpolysiloxane endblocked at both terminals by dimethylvinylsiloxy groups,
dimethylsiloxane-methylvinylsiloxane copolymer endblocked at both terminals by trimethylsiloxy groups,
dimethylsiloxane-methylvinylsiloxane copolymer endblocked at both terminals by dimethylvinylsiloxy groups,
methyltri(dimethylvinylsiloxy)silane,
methylphenylpolysiloxane endblocked at both terminals by dimethylvinylsiloxy groups,
dimethylsiloxane-methylvinylsiloxane copolymer endblocked at both terminals by dimethylphenylsiloxy groups, and
dimethylsiloxane-methylvinylsiloxane-methylphenylsiloxane copolymer endblocked at both terminals by dimethylvinylsiloxy groups.
   In addition, the specific examples of component (A) also apply here.

Specific examples of the organosilane that lacks the organic functional group and contains at least two silicon-bonded hydrogen atoms per molecule are the specific examples of component (B), and in addition an alkylsilane that contains two silicon-bonded hydrogen atoms and a silylated aliphatic hydrocarbon that contains two silicon-bonded hydrogen atoms.

The organopolysiloxane that lacks the organic functional group and contains at least two silicon-bonded hydrogen atoms per molecule can be exemplified by the specific examples of component (B); methylhydrogensiloxane oligomers, as represented by the formulas (HMe₂Si)₂O, (HMe₂SiO)₂SiMe₂, (HMe₂Si)(OSiMe₂)₂(OSiMe₂H), and (HMe₂SiO)₃SiMe; cyclic methylhydrogensiloxane oligomers (degree of polymerization=4 to 6); methyltri(dimethylhydrogensiloxy)silane; tetra(dimethylhydrogensiloxy)silane; methylhydrogenpolysiloxane with a degree of polymerization of 2 to 30 endblocked at both terminals by trimethylsiloxy groups; dimethylsiloxane-methylhydrogensiloxane copolymer with a degree of polymerization of 2 to 30 endblocked at both terminals by trimethylsiloxy groups; and dimethylpolysiloxane with a degree of polymerization of 3 to 30 endblocked at both terminals by dimethylhydrogensiloxy groups.

While all of these contain at least two silicon-bonded hydrogen atoms per molecule, the organosiloxane oligomers and organopolysiloxanes preferably contain an average of at least two silicon-bonded hydrogen atoms per molecule.

The organopolysiloxane that contains at least one organic functional group per molecule and at least two silicon-bonded hydrogen atoms per molecule can be specifically exemplified by
dimethylsiloxane-methyl(3-methacryloxypropyl)siloxane copolymer endblocked at both terminals by dimethylhydrogensiloxy groups,
dimethylsiloxane-methylhydrogensiloxane copolymer endblocked at both terminals by dimethyl(3-methacryloxypropyl)siloxy groups,
dimethylsiloxane-methyl(3-glycidoxypropyl)siloxane copolymer endblocked at both terminals by dimethylhydrogensiloxy groups, and
dimethylsiloxane-methylhydrogensiloxane copolymer endblocked at both terminals by dimethyl(3-glycidoxypropyl)siloxy groups.
   While all of these contain at least two silicon-bonded hydrogen atoms per molecule, the organosiloxane oligomers and organopolysiloxanes preferably contain an average of at least two silicon-bonded hydrogen atoms per molecule.

The molar ratio of the silicon-bonded hydrogen atoms to the silicon-bonded alkenyl groups in the preceding hydrosilylation reaction-curable organopolysiloxane compositions may be a molar ratio sufficient to bring about the formation of a cured layer through sufficient crosslinking between the alkenyl-containing organopolysiloxane and the SiH-containing organosilane or organopolysiloxane. While the molar ratio is preferably greater than 1:1, it may be 0.5 to 1.

The hydrosilylation reaction catalyst in the preceding hydrosilylation reaction-curable organopolysiloxane compositions is exemplified by the same examples as for component (C), and is preferably used in the same amount.

The above-described compositions comprising the organic functional group-containing, hydrosilylation reaction-curable organopolysiloxane preferably contain a hydrosilylation reaction retarder since the hydrosilylation reaction proceeds even at ambient temperature. The hydrosilylation reaction retarder can be exemplified by the same examples as for the hydrosilylation reaction retarder used for the hydrosilylation reaction-curable organopolysiloxane resin composition comprising components (A), (B), and (C), and is preferably used in the same amount. The above-described compositions comprising the organic functional group-containing, hydrosilylation reaction-curable organopolysiloxane may contain microparticulate reinforcing silica as long as the optical transparency of the cured product is not impaired.

The composition comprising the organic functional group-containing, hydrosilylation reaction-curable organopolysiloxane is coated on the fiber-reinforced film made of a cured organopolysiloxane resin, and is cured by standing at ambient temperature or by heating. Curing by the application of heat is required in those instances where this composition contains a hydrosilylation reaction retarder and is therefore heat-curable.

A cured organopolysiloxane resin film having gas barrier properties of the second embodiment of the present invention is characterized by comprising a fiber-reinforced film made of a cured organopolysiloxane resin which is transparent in the visible region and obtained by a crosslinking reaction between

(A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
(b) a silanol group-containing cured organopolysiloxane layer free from the organic functional group
is interposed between the aforementioned fiber-reinforced film and the aforementioned transparent inorganic layer.

(b) A silanol group-containing cured organopolysiloxane layer free from the organic functional group is a silanol group-containing cured organopolysiloxane layer free from the organic functional group produced by a condensation reaction-crosslinking of (b-1) an organic functional group-free and silicon-bonded hydrolysable groups-containing organosilane or a composition thereof, or a silanol group-containing cured organopolysiloxane layer free from the organic functional group produced by a condensation reaction-crosslinking of (b-2) an organic functional group-free and silicon-bonded hydrolysable groups-containing organopolysiloxane or a composition thereof.

The silanol-containing cured organopolysiloxane layer free from the organic functional group can be formed by coating the fiber-reinforced film made of a cured organopolysiloxane resin with an organosilane that contains three silicon-bonded hydrolyzable groups per molecule and lacks the organic functional group and carrying out a hydrolysis/condensation reaction in the presence or absence of an hydrolysis/condensation reaction catalyst. Formation can also be carried out by coating the fiber-reinforced film made of a cured organopolysiloxane resin with a mixture of an organosilane that contains three silicon-bonded hydrolyzable groups per molecule and lacks the organic functional group and an organosilane that contains one or two silicon-bonded hydrolyzable groups per molecule and lacks the organic functional group, and carrying out a hydrolysis/condensation reaction in the presence or absence of an hydrolysis/condensation reaction catalyst. Formation can also be carried out by using, instead of the aforementioned organosilane, an organopolysiloxane that contains at least three silicon-bonded hydrolyzable groups per molecule and lacks the organic functional group, or composition thereof.

Specific examples of the aforementioned organosilanes and organopolysiloxane and specific examples of the hydrolysis/condensation reaction catalyst are the same as those already explained in paragraphs [0099] to [0112].

The condensation-reactive group in the organic functional group-containing, condensation reaction-curable organosilane and the organic functional group-containing, condensation reaction-curable organopolysiloxane is silanol group and a silicon-bonded hydrolyzable group, which can be exemplified by alkoxy, alkenyloxy, acyloxy, ketoxime, and alkylamino, wherein the alkoxy is preferred and methoxy and ethoxy are more preferred considering the volatilization behavior of alcohols produced by hydrolysis thereof.

A typical example of the organic functional group-free organosilane that contains three silicon-bonded hydrolyzable groups per molecule is a hydrophobic organotrialkoxysilane represented by the formula R⁸Si(OR⁶)₃ (in the formula, R⁸ is C₁ to C₆ alkyl, C₂ to C₆ alkenyl, or phenyl group, and R⁶ is C₁ to C₆ alkyl). C₂ to C₆ alkenyl means alkenyl group having two to six carbon atoms.

Specific examples are alkyltrialkoxysilanes exemplified by methyltrimethoxysilane, methyltriethoxysilane, methyltripropoxysilane, ethyltrimethoxysilane, and ethyltripropoxysilane, phenyltrialkoxysilanes exemplified by phenyltrimethoxysilane and phenyltriethoxysilane, and vinyltrialkoxysilanes exemplified by vinyltrimethoxysilane and vinyltriethoxysilane.

The organic functional group-free organosilane that contains four silicon-bonded hydrolyzable groups in each molecule is exemplified by tetraalkoxysilane such as tetraethoxysilane and tetrapropoxysilane.

Examples of the organic functional group-free organopolysiloxane that contains at least three silicon-bonded hydrolyzable groups per molecule are the partial hydrolysis and condensation product of a hydrophobic organotrialkoxysilane represented by the formula R⁸Si(OR⁶)₃ (in the formula, R⁸ is C₁ to C₆ alkyl, C₂ to C₆ alkenyl, or phenyl group, and R⁶ is C₁ to C₆ alkyl) and the partial condensation reaction product which retains four silicon-bonded alkoxy groups of a hydrophobic organotrialkoxysilane represented by the formula R⁸Si(OR⁶)₃ and a silanol-endblocked dimethylpolysiloxane of which degree of polymerization is 2 to 50.

The aforementioned condensation reaction-curable organic functional group-free organosilane or a composition thereof, or the aforementioned condensation reaction-curable organic functional group-free organopolysiloxane or a composition thereof can be coated on the fiber-reinforced film made of a cured organopolysiloxane resin and cured by standing at ambient temperature or heating. The auxiliary use of heating or a hydrolysis/condensation reaction catalyst is necessary in those instances where the silicon-bonded hydrolyzable group does not undergo humidity-induced hydrolysis/condensation or is not susceptible to hydrolysis/condensation.

The hydrolysis/condensation reaction catalyst can be exemplified by tetraalkoxytitanium, alkoxytitanium chelates, tetraalkoxyzirconium, trialkoxyaluminum, organotin compounds exemplified by dialkyltin dicarboxylate salts and tin salts of a tetracarboxylic acid, and organic amines.

The aforementioned organic functional group-free, condensation reaction-curable organosilane composition and the organic functional group-free, condensation reaction-curable organopolysiloxane composition may contain a microparticulate reinforcing silica insofar as the optical transmittance of the cured product is not impaired.

Viewed from the standpoint of adhesion of the transparent inorganic layer selected from the group consisting of the silicon oxynitride layer, silicon nitride layer, and silicon oxide layer, the silanol group-containing cured organopolysiloxane layer contains preferably 0.5 to 40 molar percent of silanol group, and more preferably 1 to 30 molar percent of silanol group relative to the whole silicon atom-bonded groups, namely, the molar ratio of silanol groups to silicon atoms in the silanol group-containing cured organopolysiloxane is preferably on average from 0.005 to 0.40, and more preferably on average from 0.01 to 0.30.

A cured organopolysiloxane resin film having gas barrier properties of the third embodiment of the first invention in the present application is characterized by comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
(c) a hydrosilyl group-containing cured organopolysiloxane layer free from the organic functional group
is interposed between the aforementioned fiber-reinforced film and the aforementioned transparent inorganic layer.

(c) A hydrosilyl group-containing cured organopolysiloxane layer free from the organic functional group is a residual hydrosilyl group-containing cured organopolysiloxane layer free from the organic functional group produced by a hydrolsilyaltion-crosslinking reaction of (c-1) an organic functional group-free hydrolsilyaltion reaction-curable organopolysiloxane composition,

This hydrosilyl group is bonded to a portion of the silicon atoms in the organopolysiloxane forming the cured organopolysiloxane.

The hydrosilyl group-containing cured organopolysiloxane layer free from the organic functional group can be formed by coating and curing, onto the fiber-reinforced film made of a cured organopolysiloxane resin, a hydrosilylation reaction-curable organopolysiloxane composition comprising (a) an organopolysiloxane that has an average of at least 1.2 alkenyl groups per molecule, (b) an organosilicon compound having at least two silicon-bonded hydrogen atoms, that is, hydrosilyl groups per molecule, and (c) a hydrosilylation reaction catalyst wherein the molar ratio of the hydrosilyl groups in component (b) to the alkenyl groups in component (a) is greater than 1.0. An average of at least 1.2 alkenyl groups is present per molecule. Based on a consideration of the curability, preferably an average of at least 1.5 alkenyl groups is present per molecule and more preferably an average of at least 2.0 is present per molecule.

When component (b) is an organosilicon compound that has two silicon-bonded hydrogen atoms per molecule, component (a) must comprise a molecule that has at least three C₂ to C₁₀ alkenyl groups per molecule in order for component (a) to cure through its addition reaction with component (b).

When component (a) has two alkenyl groups per molecule, component (b) must comprise a molecule that contains at least three silicon-bonded hydrogen atoms per molecule in order for component (a) to cure through its addition reaction with component (b).

While the major portion of component (a) must be an organopolysiloxane containing at least three alkenyl groups per molecule or an organopolysiloxane containing at least two alkenyl groups per molecule, component (a) may contain an organopolysiloxane containing one alkenyl group per molecule.

From the standpoint of adhesion of the transparent inorganic layer, the molar ratio of the hydrosilyl groups in component (b) to the alkenyl groups in component (a) is preferably from at least 1.05 to no more than 1.5 and more preferably from at least 1.1 to no more than 1.5.

However, since there is a risk that the silicon-bonded hydrogen atoms (hydrosilyl groups) may be consumed by mechanisms other than the hydrosilylation reaction, it is necessary to confirm that silicon-bonded hydrogen atoms (hydrosilyl groups) remain after curing. Detection of the absorption peak for the hydrosilyl group by means of an infrared spectrophotometer can be used for confirmation.

Component (a) can be exemplified by the same examples as provided for component (A), and additional examples are the same examples as provided above for the organopolysiloxane that contains at least two silicon-bonded alkenyl groups per molecule and that lacks the organic functional group (see paragraph [0119]). Component (b) can be exemplified by the same examples as provided for component (B), and additional examples are the same examples as provided above for the organopolysiloxane that contains at least two silicon-bonded hydrogen atoms per molecule and that lacks the organic functional group (see paragraph [0121], [0123]). Component (c) can be exemplified by the same examples as provided above for component (C).

The hydrosilylation reaction-curable composition comprising components (a), (b), and (c) preferably incorporates a hydrosilylation reaction retarder since the hydrosilylation reaction proceeds even at ambient temperature. The hydrosilylation reaction retarder can be exemplified by the same examples as for the hydrosilylation reaction retarder used for the composition comprising components (A), (B), and (C) and may be used in the same amount.

The hydrosilylation reaction-curable organopolysiloxane composition comprising components (a), (b), and (c), and a hydrosilylation reaction-curable organopolysiloxane composition comprising components (a), (b), (c), and a hydrosilylation reaction retarder can be coated and cured in the same curing condition for the hydrosilylation reaction-curable organofunctional group-containing organopolysiloxane composition (see paragraph [0127]).

A cured organopolysiloxane resin film having gas barrier properties of the fourth embodiment of the first invention in the present application is characterized by comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₉ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
(d) a layer of cured organopolysiloxane having organic groups produced by polymerization between polymerizable organic functional groups of an organopolysiloxane having two or more polymerizable organic functional groups in one molecule
is interposed between the aforementioned fiber-reinforced film and the aforementioned transparent inorganic layer.

Based on a consideration of the curability of the polymerizable organic functional group-containing organopolysiloxane, this organopolysiloxane must comprise a molecule that contains at least two polymerizable organic functional groups per molecule when the polymerizable organic functional groups participate in a chain-growth polymerization, while this organopolysiloxane must comprise a molecule that has at least three polymerizable organic functional groups per molecule when a step-growth polymerization operates. The polymerizable organic functional group may be up to 100 mole % of the total organic groups that are bonded through the C—Si bond in the polymerizable organic functional group-containing curable organopolysiloxane. For example, this value is 33.3 mole % in Synthesis Example 3 hereinafter described.

These polymerizable organic functional groups form crosslink points and render the organopolysiloxane curable. The transparent inorganic layer selected from the silicon oxynitride layer, silicon nitride layer, and silicon oxide layer readily adheres to the cured film formed by polymerization between the polymerizable organic functional groups in the polymerizable organic functional group-containing organopolysiloxane under consideration. Viewed from the standpoint of adhesion of the transparent inorganic layer, the polymerizable organic functional group is preferably an oxygen-containing polymerizable organic functional group, and more preferably an oxygen-containing polymerizable organic functional group consisting of carbon atoms, hydrogen atoms and oxygen atoms, or consisting of carbon atoms, hydrogen atoms, oxygen atoms and nitrogen atoms. The oxygen-containing organic functional group preferably contains a carbonyl group, or a polar bond, e.g., a carboxylic acid ester bond, carboxylic acid amide bond, ether bond (C—O—C) and so forth.

The layer of cured organopolysiloxane containing organic groups produced by the polymerization of the polymerizable organic functional groups with each other is formed by coating the polymerizable organic functional group-containing organopolysiloxane on the fiber-reinforced film, particularly fiber-reinforced free-standing film made of a cured organopolysiloxane resin and curing by polymerizing the polymerizable organic functional groups with each other. When these polymerizable organic functional groups undergo polymerization with each other, the organic groups produced by the polymerization become crosslinking chains between such organopolysiloxanes, and the organopolysiloxanes then cure by assuming a network configuration.

Viewed from the standpoint of adhesion of the transparent inorganic layer selected from a silicon oxynitride layer, silicon nitride layer, and silicon oxide layer, the organic group produced by polymerization between polymerizable organic functional groups is preferably an oxygen-containing organic group, and more preferably is oxygen-containing organic group consisting of carbon atoms, hydrogen atoms and oxygen atoms, or consisting of carbon atoms, hydrogen atoms, oxygen atoms and nitrogen atoms. The oxygen-containing organic group preferably contains a carbonyl group, or a polar bond, e.g., a carboxylic acid ester bond, carboxylic acid amide bond, ether bond (C—O—C) and so forth.

Based on a consideration of the ease of polymerization, the polymerizable organic functional group in the polymerizable organic functional group-containing organopolysiloxane is preferably the aforementioned acrylic functional group, epoxy functional group, oxetanyl functional group, or alkenyl ether group.

Other examples are a crotonyl functional group and a cinnamoyl functional group, which can be regarded as types of the acrylic functional group.
The acrylic functional group is also known as acryloyl functional group, and its representative example is represented by the formula CH₂═CHCO—.

Preferred acrylic functional groups can be exemplified by an acryloxy functional group and acrylamide functional group;

Preferred acryloxy functional groups can be exemplified by an acryloxyalkyl group represented by CH₂═CHCOOR³— (wherein R³ in the formulas is an alkylene group such as propylene) such as acryloxypropyl group, and by a methacryloxyalkyl group represented by CH₂═CH(CH₃)COOR³— (wherein R³ in the formula is an alkylene group such as propylene) such as methacryloxypropyl group.
Preferred acrylamide functional groups can be exemplified by a N-alkyl-N-acrylamidealkyl group represented by CH₂═CHCON(R⁴)R³— (wherein R³ is an alkylene group such as propylene, and R⁴ is an alkyl group such as methyl) such as N-alkyl-N-acrylamidepropyl group, and by a N-alkyl-N-methacrylamide group represented by CH₂═C(CH₃)CON(R⁴)R³— (wherein R³ is an alkylene group such as propylene, and R⁴ is an alkyl group such as methyl) such as N-alkyl-N-methacrylamidepropyl group.
The alkylene group here preferably has 2 to 6 carbon atoms

Preferred specific examples of the epoxy functional group are epoxymethyl group and 2-epoxyethyl group; a glycidoxyalkyl group such as β-glycidoxyethyl group and 3-glycidoxpropyl group; and an epoxycyclohexylalkyl group such as β-(3,4-epoxycyclohexyl)ethyl and 3-(3,4-epoxycyclohexyl)propyl. Preferred specific examples of the oxetanyl functional group are 2-oxetanylbutyl group and 3-(2-oxetanylbutyloxy)propyl group.

Preferred specific examples of the alkenyl ether functional group are vinyloxyalkyl group, allyloxyalkyl group, and allyloxyphenyl group. This alkenyl has preferably 2 to 6 carbon atoms.

When the polymerizable organic functional group is an acrylic functional group or alkenyl ether group, for example, a vinyloxyalkyl group, polymerization can be effected by exposure to high energy radiation or actinic energy radiation, such as ultraviolet radiation, an electron beam, gamma radiation, and so forth. Polymerization can also be brought about by heating when the polymerizable organic functional group is an acrylic functional group. A radical polymerization initiator may also be used in the case of polymerization by the application of heat. When the polymerizable organic functional group is an epoxy functional group or an oxetanyl functional group, ring-opening polymerization can be brought about by exposure to ultraviolet radiation in the presence of a photopolymerization initiator. Ring-opening polymerization can also be brought about by the co-use of a catalyst such as an aliphatic amine, alicyclic amine, aromatic amine, imidazole, organic dicarboxylic acid, organic dicarboxylic anhydride, and so forth.

The polymerizable organic functional group-containing organopolysiloxane can be specifically exemplified by the following: dimethylsiloxane-methyl(3-methacryloxypropyl)siloxane copolymer endblocked at both terminals by trimethylsiloxy groups, dimethylpolysiloxane endblocked at both terminals by dimethyl(3-methacryloxypropyl)siloxy groups, dimethylsiloxane-methyl(3-methacryloxypropyl)siloxane copolymer endblocked at both terminals by dimethyl(3-methacryloxypropyl)siloxy groups, 3-methacryloxypropylpolysilsesquioxane, 3-methacryloxypropylsilsesquioxane-phenylsilsesquioxane copolymer, 3-methacryloxypropylsilsesquioxane-methylsilsesquioxane copolymer; dimethylsiloxane-methyl(3-glycidoxypropyl)siloxane copolymer endblocked at both terminals by trimethylsiloxy groups, dimethylpolysiloxane endblocked at both terminals by dimethyl(3-glycidoxypropyl)siloxy groups, dimethylsiloxane-methyl(3-glycidoxypropyl)siloxane copolymer endblocked at both terminals by dimethyl(3-glycidoxypropyl)siloxy groups, 3-glycidoxypropylpolysilsesquioxane,

β-(3,4-epoxycyclohexyl)ethylpolysilsesquioxane, 3-glycidoxypropylsilsesquioxane-phenylsilsesquioxane copolymer, and 3-glycidoxypropylsilsesquioxane-methylsilsesquioxane copolymer.

A cured organopolysiloxane resin film having gas barrier properties of the fifth embodiment of the first invention in the present application is characterized by comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is interposed between the aforementioned fiber-reinforced film and the aforementioned transparent inorganic layer.

The layer of cured organopolysiloxane containing organic groups produced by polymerizing the polymerizable organic functional groups with each other and reacting the crosslinking groups with each other can also be formed by coating the fiber-reinforced film, particularly free-standing film made of a cured organopolysiloxane resin with a curable organopolysiloxane that contains at least one polymerizable organic functional group and at least one crosslinking group per molecule or a composition thereof, polymerizing the polymerizable organic functional groups with each other and reacting the crosslinking groups with each other to cure the curable organopolysiloxane or composition thereof.

The curing mechanism for the polymerizable organic functional group-containing curable organopolysiloxane composition preferably proceeds through a condensation reaction or a hydrosilylation reaction.

The crosslinking group is exemplified by silanol group and silicon-bonded hydrolyzable groups for the condensation reaction, and an alkenyl group and hydrosilyl group for the hydrosilylation reaction. Preferred silicon-bonded hydrolyzable groups can be exemplified by alkoxy, alkenyloxy, acyloxy, ketoxime, and alkylamino, wherein alkoxy is preferred and methoxy and ethoxy are more preferred considering the volatilization behavior of alcohols produced by hydrolysis thereof. The polymerizable organic functional group is the same as the aforementioned one.

An example of a curable organopolysiloxane that contains at least one polymerizable organic functional group and crosslinking group per molecule is a humidity-curable organopolysiloxane that contains at least three silicon-bonded hydrolyzable groups per molecule and at least one polymerizable organic functional group per molecule.

The following are examples of compositions comprising the condensation reaction-curable organopolysiloxane that contains at least one polymerizable organic functional group and crosslinking group per molecule:

(1) a curable composition comprising an organopolysiloxane that contains at least one polymerizable organic functional group per molecule and at least three silicon-bonded hydrolyzable groups per molecule, and a condensation reaction catalyst.

(2) a curable composition comprising an organopolysiloxane that contains at least one polymerizable organic functional group per molecule and one or two silicon-bonded hydrolyzable groups per molecule, and an organopolysiloxane that lacks the polymerizable organic functional group and contains at least three silicon-bonded hydrolyzable groups, and a condensation reaction catalyst.

The following are examples of compositions comprising a hydrosilylation reaction-curable organopolysiloxane that has at least one polymerizable organic functional group and at least one cross-linking group per molecule:

(1) a composition comprising an organopolysiloxane that contains at least two silicon-bonded alkenyl groups per molecule and at least one polymerizable organic functional group per molecule, an organosilane that contains at least two silicon-bonded hydrogen atoms per molecule and lacks the polymerizable organic functional group, and a hydrosilylation reaction catalyst, and

(2) a composition comprising an organopolysiloxane that contains at least one polymerizable organic functional group per molecule and at least two silicon-bonded alkenyl groups per molecule, an organopolysiloxane that contains at least two silicon-bonded hydrogen atoms per molecule and lacks the polymerizable organic functional group, and a hydrosilylation reaction catalyst.

Additional examples are

(3) a composition comprising an organopolysiloxane that contains at least two silicon-bonded alkenyl groups per molecule and that lacks the polymerizable organic functional group, an organopolysiloxane that contains at least one polymerizable organic functional group per molecule and at least two silicon-bonded hydrogen atoms per molecule, and a hydrosilylation reaction catalyst, and

(4) a composition comprising an organopolysiloxane that contains at least one polymerizable organic functional group per molecule and at least two silicon-bonded alkenyl groups per molecule, an organopolysiloxane that contains at least one polymerizable organic functional group per molecule and at least two silicon-bonded hydrogen atoms per molecule, and a hydrosilylation reaction catalyst.

Because the hydrosilylation reaction proceeds even at ambient temperature, these compositions (1) to (4) preferably incorporate a hydrosilylation reaction retarder.

This hydrosilylation reaction retarder is exemplified by the same hydrosilylation reaction retarders as cited for the composition comprising components (A), (B), and (C) and is preferably used in the same amount.

The molar ratio of the silicon-bonded hydrogen atoms to the silicon-bonded alkenyl groups in the preceding compositions may be a molar ratio sufficient to bring about the formation of a cured layer through sufficient crosslinking between the alkenyl-containing organopolysiloxane and the SiH-containing organosilane or organopolysiloxane. While the molar ratio is preferably greater than 1:1, it may be 0.5 to 1.

Specific examples of the organopolysiloxane that contains at least one polymerizable functional group per molecule and at least two silicon-bonded alkenyl groups per molecule are as follows:
dimethylsiloxane-methyl(3-methacryloxypropyl)siloxane copolymer endblocked at both terminals by dimethylvinylsiloxy groups,
dimethylsiloxane-methylvinylsiloxane copolymer endblocked at both terminals by dimethyl(3-methacryloxypropyl)siloxy group,
dimethylsiloxane-methyl(3-glycidoxypropyl)siloxane copolymer endblocked at both terminals by dimethylvinylsiloxy groups, and
dimethylsiloxane-methylvinylsiloxane copolymer endblocked at both terminals by dimethyl(3-glycidoxypropyl)siloxy groups.

Specific examples of the organopolysiloxane that contains at least one organic functional group per molecule and at least two silicon-bonded hydrogen atoms per molecule are as follows:
dimethylsiloxane-methyl(3-methacryloxypropyl)siloxane copolymer endblocked at both terminals by dimethylhydrogensiloxy groups,
dimethylsiloxane-methylhydrogensiloxane copolymer endblocked at both terminals by dimethyl(3-methacryloxypropyl)siloxy groups,
dimethylsiloxane-methyl(3-glycidoxypropyl)siloxane copolymer endblocked at both terminals by dimethylhydrogensiloxy groups, and
dimethylsiloxane-methylhydrogensiloxane copolymer endblocked at both terminals by dimethyl(3-glycidoxypropyl)siloxy groups.

Specific examples of the organosilane that contains at least two silicon-bonded hydrogen atoms per molecule and that lacks the polymerizable organic functional group, the organopolysiloxane that contains at least two silicon-bonded hydrogen atoms per molecule and that lacks the polymerizable organic functional group, and the organopolysiloxane that contains at least two silicon-bonded alkenyl groups per molecule and that lacks the polymerizable organic functional group are the same those as already described.

The aforementioned composition comprising a polymerizable organic functional group-containing, condensation reaction-curable organopolysiloxane and the aforementioned composition comprising a polymerizable organic functional group-containing, hydrosilylation reaction-curable organopolysiloxane may contain microparticulate reinforcing silica insofar as the optical transparency of the cured product is not impaired.

The aforementioned polymerizable organic functional group-containing curable organopolysiloxane is thinly coated on the fiber-reinforced film made of a cured organopolysiloxane resin, and curing is brought about by polymerizing the polymerizable organic functional groups with each other and reacting the crosslinking groups with each other. This polymerization between the polymerizable organic functional groups is carried out as described above. The crosslinking mechanism for the curable organopolysiloxane itself can be exemplified by condensation reaction and hydrosilylation reaction.

When the polymerizable organic functional groups are polymerized with each other among a plurality of curable organopolysiloxanes that have at least one polymerizable organic functional group per molecule and the curable organopolysiloxanes are crosslinked, the plurality of organopolysiloxanes then cure by assuming a network configuration.

The aforementioned polymerizable organic functional group-containing, condensation reaction-curable organopolysiloxane per se or a composition thereof is coated on the fiber-reinforced film made of a cured organopolysiloxane resin, and curing is effected by a condensation reaction among the silicon-bonded hydrolyzable groups brought about by standing at ambient temperature or heating and the polymerizable organic functional groups are polymerized with each other. The auxiliary use of heating or a hydrolysis/condensation reaction catalyst as described above is necessary in those instances where humidity-induced hydrolysis/condensation does not occur or hydrolysis/condensation proceeds with difficulty.

The aforementioned composition comprising the polymerizable organic functional group-containing, hydrosilylation reaction-curable organopolysiloxane is coated on the fiber-reinforced film made of a cured organopolysiloxane resin, and curing is effected by a hydrosilylation reaction brought about by standing at ambient temperature or heating and by polymerization of the polymerizable organic functional groups with each other. Curing by the application of heat is required in those instances where this composition contains a hydrosilylation reaction retarder and is therefore heat-curable. The conditions for polymerizing the polymerizable organic functional groups are as described in paragraph [0155].

The cured organopolysiloxane resin film having gas barrier properties according to 1 can be produced by the following process.

(I) forming a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane,
by coating, on a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst; and then
(II) forming a transparent inorganic layer selected from the group consisting of a silicon oxynitride layer, silicon nitride layer, and silicon oxide layer, by vapor deposition, on the aforementioned cured organopolysiloxane layer.
When the aforementioned organic functional group-containing curable organosilane per se or a composition thereof, the aforementioned organic functional group-containing curable organopolysiloxane per se or a composition thereof, the aforementioned organic functional group-free and silanol group-containing curable organosilane or a composition thereof, the aforementioned organic functional group-free and silanol group-containing curable organopolysiloxane or a composition thereof, the aforementioned organic functional group-free and hydrosilyl group-containing curable organosilane or a composition thereof, the aforementioned organic functional group-free and hydrosilyl group-containing curable organopolysiloxane or a composition thereof, the aforementioned polymerizable organic functional group-containing curable organopolysiloxane per se or a composition thereof, or the aforementioned polymerizable organic functional group- and crosslinking group-containing curable organopolysiloxane per se or a composition thereof is either a high viscosity liquid or a solid at ambient temperature in the production of the cured organopolysiloxane resin film having gas barrier properties for the first to fifth embodiment of the first invention, it is preferably rendered coatable as a thin film by dissolution in an organic solvent. Once coating on the fiber-reinforced film made of a cured organopolysiloxane film has been carried out, curing is preferably effected after the organic solvent has been evaporated off, said organic solvent being evaporated off by heating at low temperature or by exposure to a hot air current.

As the organic solvent for this purpose, an organic solvent that does not cause hydrolysis of silicon-bonded hydrogen atoms and is easily evaporated off by heating to no more than 200° C. Suitable organic solvents can be exemplified by ketones such as acetone, methyl ethyl ketone, methyl isobutyl ketone, and so forth; aromatic hydrocarbons such as toluene, xylene, and so forth; aliphatic hydrocarbons such as heptane, hexane, octane, and so forth; ethers such as THF, dioxane, and so forth; as well as dimethylformamide and N-methylpyrrolidone.

These organic solvents are used in a quantity that enables dissolution of the aforementioned organosilane, organosilane composition, organopolysiloxane, or organopolysiloxane composition and coating thereof in a thin layer.

Brush application, blade coating, roller coating, spin coating, spraying, and dip coating are examples of methods that can be used to coat the surface of the fiber-reinforced film made of a cured organopolysiloxane resin with the aforementioned organic functional group-containing curable organosilane per se or a composition thereof, the aforementioned organic functional group-containing curable organopolysiloxane per se or a composition thereof, the aforementioned polymerizable organic functional group-containing curable organopolysiloxane per se or a composition thereof, or polymerizable organic functional group- and crosslinking group-containing curable organopolysiloxane per se or composition thereof, and so on.

The thickness of the cured organopolysiloxane layer (a), (b), (c), (d), or (e) is to be a thickness sufficient to also coat elevations of microscopic depressions and elevations on the surface of the fiber-reinforced film made of a cured organopolysiloxane resin, and a thin layer is preferred. That is, a thickness appropriate for a primer layer is preferred.

The cured organopolysiloxane layer (a), (b), (c), (d), or (e) coats over microscopic contaminants (foreign material) attached on the surface of the fiber-reinforced film made of a cured organopolysiloxane resin during the production process, and fills in depressions generated on the surface of the fiber-reinforced film made of a cured organopolysiloxane resin during the production process. Because of this, when the transparent inorganic layer selected from the group consisting of a silicon oxynitride layer, silicon nitride layer, and silicon oxide layer is formed thereon, a good quality transparent inorganic layer, that is, transparent inorganic film selected from the group consisting of a silicon oxynitride layer, that is, silicon oxynitride film, silicon nitride layer, that is, silicon nitride film, and silicon oxide layer, that is, silicon oxide film can be formed, wherein the production of voids and cracks in this transparent inorganic layer is prevented.

A cured organopolysiloxane resin film having gas barrier properties according to claim 9 of the second invention in the present application is characterized by comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a silicon oxynitride layer that is formed on the fiber-reinforced film,
wherein a molar ratio of hydrosilyl groups of component (B) to unsaturated aliphatic hydrocarbyls of component (A) is within the range of 1.05 to 1.50, and the aforementioned cured organopolysiloxane resin has hydrosilyl groups.

The aforementioned cured organopolysiloxane resin film having gas barrier properties according to claim 9 is produced by forming a silicon oxynitride layer by a ion plating procedure on a fiber-reinforced film made of a hydrosilyl group-containing cured organopolysiloxane resin which is transparent in the visible region and is obtained by a crosslinking reaction between
(A) an organopolysiloxane resin that is represented by the average siloxane unit formula

RₐSiO_{(4-a)/2} (1)
(in the formula, R is a C₁ to C₁₀ monovalent hydrocarbyl and a is a number with an average value in the range of 0.5<a<2) and that has an average of at least 1.2 C₂ to C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst.

The above-cited components (A) to (C), the cured organopolysiloxane resin, and the fiber-reinforced film made of a cured organopolysiloxane resin are the same as those already explained.

The fiber-reinforced film made of a hydrosilylation group-containing cured organopolysiloxane resin can be formed by curing at a molar ratio of the hydrosilyl groups in component (B) to the unsaturated aliphatic hydrocarbyl groups in component (A) of 1.05 to 1.50. However, since there is a risk that the silicon-bonded hydrogen atoms, that is, hydrosilyl group may be consumed by mechanisms other than the hydrosilylation reaction, it is necessary to confirm that silicon-bonded hydrogen atoms, that is, hydrosilyl group remain after curing. Detection of the absorption peak for the hydrosilyl group by means of an infrared spectrophotometer can be used for confirmation.

The presence of hydrosilyl groups in the fiber-reinforced film made of a cured organopolysiloxane resin enables the formation of a good quality silicon oxynitride layer when a silicon oxynitride layer is formed on the surface of this film by ion plating.

The cured organopolysiloxane resin in the cured organopolysiloxane resin film, particularly fiber-reinforced free-standing film having gas barrier properties of the first invention and the second invention is a heat-resistant crosslinked material that exhibits a poor water absorption property, and as a consequence they do not impair film formation during the vapor deposition of silicon oxynitride, silicon nitride, or silicon oxide and in particular do not impair film formation by the evaporation of low molecular weight components during vacuum vapor deposition (vacuum film formation). As a consequence, they are well adapted for the formation of a gas barrier inorganic layer on their surface using a variety of vacuum vapor deposition (vacuum film formation) methods.

Thus, a cured organopolysiloxane resin film having gas barrier properties, comprising a silicon oxynitride layer, silicon nitride layer, or silicon oxide layer which has been vapor-deposited on a fiber-reinforced film, particularly fiber-reinforced free-standing film made of a cured organopolysiloxane that lack a specific absorption band in the visible region from 400 nm to 800 nm, can be produced by the vapor deposition and preferably the vacuum vapor deposition, that is, vacuum film formation of silicon oxynitride, silicon nitride, or silicon oxide at a temperature for the fiber-reinforced film, particularly fiber-reinforced free-standing film made of a cured organopolysiloxane of no more than 300° C. This temperature condition of no more than 300° C. is necessary in order to prevent deformation and/or pyrolysis of the fiber-reinforced film, particularly fiber-reinforced free-standing film made of a cured organopolysiloxane, and a more preferred temperature is no more than 250° C.

In the cured organopolysiloxane resin film, particularly fiber-reinforced free-standing film having gas barrier properties of the first invention, the cured organopolysiloxane layer (a), (b), (c), (d), or (e) is formed on a fiber-reinforced film made of a cured organopolysiloxane resin, and a silicon oxynitride layer, that is, silicon oxynitride film, silicon nitride layer, that is, silicon nitride film, or silicon oxide layer, that is, silicon oxide film is formed thereon.

In the cured organopolysiloxane resin film, particularly free-standing film having gas barrier properties of the second invention, a silicon oxynitride layer produced by reactive ion plating is formed on a fiber-reinforced film, particularly fiber-reinforced free-standing film made of a hydrosilyl group-containing cured organopolysiloxane resin.

As a consequence, the silicon oxynitride layer, that is, silicon oxynitride film is uniform and there is good adhesiveness between the individual layers and the individual layers are thus not easily delaminated from each other. The silicon oxynitride is the noncrystalline material.

The silicon oxynitride layer, that is, silicon oxynitride film, silicon nitride layer, that is, silicon nitride film, and silicon oxide layer, that is, silicon oxide film each exhibit an excellent optical transparency and for this reason the optical transparency of the fiber-reinforced film made of a cured organopolysiloxane resin is not impaired; however, the oxygen fraction (O/(O+N)) in the silicon oxynitride layer, that is, silicon oxynitride film must be about 40% to 80% in order for it to exhibit an optical transparency of 90% or more. Here, the amount of oxygen can be determined according to XPS measurements from the intensity ratio between the peak due to SiO in the vicinity of 105 eV for Si 2p and that due to SiOxNy in the vicinity of 103 to 104 eV for Si 2p.

The preferred ranges for the values of x and y in the silicon oxynitride (SiOxNy) are values that provide an oxygen fraction (O/(O+N)) of approximately 40% to 80%.

Among the three layers cited above, the silicon oxynitride layer, that is, silicon oxynitride film is the best from the standpoint of high barrier properties and transparency.

Silicon oxynitride is a composite of silicon oxide and silicon nitride, and its transparency increases at a high silicon oxide content while its gas barrier performance increases at a high silicon nitride content. Silicon oxynitride is also known as nitrided silicon oxide and also simply as SiON.

Vapor deposition is a method used to form the silicon oxynitride layer, that is, silicon oxynitride film on the fiber-reinforced film made of a cured organopolysiloxane resin, and a reactive physical vapor deposition procedure is preferred among the vapor deposition procedure. Among the reactive physical vapor deposition procedure, ion plating is preferred, followed by reactive sputtering. Because these procedures enable vapor deposition to be carried out at relatively low temperatures, i.e., 300° C. and below, there is almost no thermal influence on the fiber-reinforced film made of a cured organopolysiloxane resin.

In the ion plating, a depositing material is ionized by generating a plasma between a substrate and a crucible holding the depositing material within a chamber; a negative voltage is applied to the substrate; and the ionized depositing material accelerated to moderate velocities, collides with the substrate to form a thin film of the depositing material. Direct current discharge excitation and high frequency excitation are typical ion plating methods.

Within the realm of ion plating, preferred one is a method in which a reactive gas is introduced into the chamber and a thin film comprising a compound between the ionized depositing material and the reactive gas is formed.

The following methods, inter alia, can be used to form a silicon oxynitride film: (1) a method in which silicon oxide or silicon dioxide is used as the depositing material and a gas functioning as a nitrogen source, e.g., nitrogen gas, nitrous oxide gas, ammonia, and so forth, is introduced into the chamber; (2) a method in which silicon nitride is used as the depositing material and oxygen gas is introduced into the chamber; and (3) a method in which silicon is used as the depositing material and oxygen gas and a gas functioning as a nitrogen source, e.g., nitrogen gas, nitrous oxide gas, ammonia, and so forth, are introduced into the chamber. The ion plating offers the advantages of good adhesiveness with the substrate and the ability to form a fine, dense silicon oxynitride film.

The method described in JP Kokai 2004-050821 (JP 2004-050821 A) is a specific example of the ion plating. This method uses an ion plating apparatus in which a hearth is provided in the lower part of a film formation chamber, a plasma gun is located in a side region of the film formation chamber, and a substrate is disposed in the upper region of the film formation chamber. A silicon oxide rod introduced into the hearth is heated by a plasma beam from the plasma gun, thereby inducing evaporation of the silicon oxide; the evaporated silicon oxide is ionized and reacts with nitrogen gas that has been introduced into the film formation chamber to give silicon oxynitride; and bonding of this to the substrate surface results in the formation of a silicon oxynitride film. In an example, the discharge current is 120 A; argon gas is employed as a carrier gas; N₂ gas is employed as a reactive gas; the pressure during film formation is 3 mTorr, that is, 0.40 Pa; and the substrate temperature is room temperature.

In reactive sputtering, inert gas ions are generated by an ion gun or plasma discharge and are accelerated by an electric field onto a target (depositing material), resulting in the ejection of elements and/or compounds at the surface and in the deposition on the substrate of ejected elements and/or compounds while reacting with a reactive gas.

A silicon oxynitride film can be formed, by the following methods: (1) a method in which silicon oxide or silicon dioxide is used as the target and argon gas and nitrogen gas are introduced into the chamber; (2) a method in which silicon nitride (Si₃N₄) is used as the target and argon gas and oxygen gas are introduced into the chamber; and (3) a method in which silicon (Si) is used as the target and argon gas, nitrogen gas, and oxygen gas are introduced into the chamber.
A two-pole sputtering apparatus or a magnetron sputtering apparatus is used as the apparatus, while a direct current procedure and high frequency are typical discharge methods. Reactive sputtering offers good control of the elemental composition and can form a fine and dense silicon oxynitride layer that is, silicon oxynitride film.

Chemical vapor deposition (CVD) is another method by which silicon oxynitride layer, that is, silicon oxynitride film can be formed on the fiber-reinforced film made of a organopolysiloxane resin, and plasma CVD, catalytic CVD, and photo-CVD are preferred among CVD methods. The reaction gases are typically monosilane gas (SiH₄), a gas that functions as a nitrogen source (e.g., nitrous oxide gas, nitric oxide gas, ammonia gas, and so forth), and hydrogen gas.

In order to form a silicon oxynitride layer, that is, silicon oxynitride film by plasma CVD, for example, monosilane gas, ammonia gas, and nitrogen gas are introduced into a vacuum container in which the fiber-reinforced film made of a cured organopolysiloxane resin has been mounted; a plasma is generated by, for example, the application of a high frequency discharge while holding the internal pressure at 0.1 to 10 Torr, that is, 13.3 to 1330 Pa; and film-forming species produced when the introduced gases are excited within the plasma are deposited on the fiber-reinforced film made of a cured organopolysiloxane resin.

In order to form a silicon oxynitride layer, that is, silicon oxynitride film by catalytic CVD, for example, monosilane gas, ammonia gas, and hydrogen gas are introduced into a vacuum container in which the fiber-reinforced film made of a cured organopolysiloxane resin is mounted; the introduced gases are decomposed and activated by a tungsten wire heated to about 1700° C. to form a silicon oxynitride layer, that is, silicon oxynitride film on the fiber-reinforced film made of a cured organopolysiloxane resin, which is being maintained at about 70° C.

In order to form a silicon oxynitride layer, that is, silicon oxynitride film by photo-CVD, for example, monosilane gas, ammonia gas, and nitrogen gas are introduced into a vacuum container in which the fiber-reinforced film made of a cured organopolysiloxane resin-is mounted; excitation is carried out by exposing the gases to ultraviolet radiation or laser light while holding the internal pressure at 133 to 13300 Pa, that is, 1 to 100 Torr; and film-forming species produced by the excitation are deposited on the fiber-reinforced film made of a cured organopolysiloxane resin.

The silicon oxynitride (SiOₓN_{y}) layer, that is, silicon oxynitride film may be formed on one side or on both sides of the fiber-reinforced film made of a cured organopolysiloxane resin. In addition, the vapor deposition process, that is, film formation process may be carried out a plurality of times.

The thickness of the silicon oxynitride (SiOₓN_{y}) layer, that is, silicon oxynitride (SiOₓN_{y}) film will vary with the application and the required gas barrier performance, but the range of 10 nm to 1 μm is preferred and the range of 10 nm to 200 nm is more preferred. An overly thick silicon oxynitride layer, that is, silicon oxynitride film impairs the flexibility of the fiber-reinforced film made of a cured organopolysiloxane resin having gas barrier properties and results in the facile introduction of cracks into the silicon oxynitride layer, that is, silicon oxynitride film itself. When too thin, the silicon oxynitride layer, that is, silicon oxynitride film is easily ruptured by contact with sources of potential damage and the gas barrier properties are readily reduced.

The silicon nitride layer, that is, silicon nitride film can be formed on the fiber-reinforced film made of a cured organopolysiloxane resin by, inter alia, vacuum vapor deposition methods, ion beam-assisted vapor deposition methods, sputtering methods, ion plating methods, and reactive physical vapor deposition methods, and can also be formed by CVD methods such as plasma CVD and thermal CVD.

The method described in JP Kokai 2004-142351 (JP 2004-142351 A) is a specific example of the formation of a silicon nitride (Si₃N₄) layer by RF magnetron sputtering. The sputtering device may be, for example, a batch-type sputtering device (SPF-530H, ANELVA Corporation). The substrate film is mounted in a chamber; a target of silicon nitride having a sinter density of 60% is mounted in the chamber; and the target-to-substrate film gap, that is, TS gap is set to 50 mm.

The interior of the chamber is then evacuated to a final vacuum of 2.5×10⁻⁴ Pa; argon gas is introduced into the chamber at a flow rate of 20 sccm; and a silicon nitride layer, that is, silicon nitride film is formed on the substrate film by RF magnetron sputtering at an applied power of 1.2 kW.

JP Kokai 2000-212747 (JP2000-212747 A) discloses a concrete example of methods to form a silicon nitride (Si₃N₄) layer by plasma CVD. A substrate film is mounted on a lower electrode, namely, earth electrode in the chamber of parallel plate type of plasma CVD apparatus PE401 which is a product of ANELVBA, and the interior of the chamber is then evacuated to a final vacuum of 0.013 Pa, that is, 0.1 mTorr. Hexamethyldisilazane vaporized by heating and nitrogen gas are introduced into the chamber. An electric power with 200 W and 13.56 Hz is applied between an upper electrode and the earth electrode to form plasma, and the pressure in the chamber is maintained at 6.5 Pa, that is, 50 mTorr to form a silicon nitride layer, that is, silicon nitride film on the substrate film.

The film thickness is suitably in the range of 5 to 500 nm and more preferably 10 to 300 nm. The silicon nitride layer, that is, silicon nitride film may be formed on one side or both sides of the fiber-reinforced film made of a cured organopolysiloxane resin. In addition, the vapor deposition process, that is, film formation process may be run a plural number of times.

The silicon oxide layer, that is, silicon oxide film may be formed on one side or on both sides of the fiber-reinforced film made of a cured organopolysiloxane resin by a physical vapor deposition, that is, PVD method such as vacuum deposition, sputtering, ion plating, and so forth, or by a chemical vapor deposition, that is, CVD method.

Vacuum deposition uses SiO₂ alone, a mixture of Si and SiO₂, a mixture of Si and SiO, or a mixture of SiO and SiO₂ as its vapor deposition source material and uses resistance heating, high frequency induction heating, or electron beam heating as its heating method.

Sputtering uses SiO₂ alone, a mixture of Si and SiO₂, a mixture of Si and SiO, or a mixture of SiO and SiO₂ as its target material and uses a direct-current discharge, alternating-current discharge, high-frequency discharge, or an ion beam as its sputtering method. Oxygen gas or steam is used as the reactive gas in reactive sputtering.

The silicon oxide (SiOₓ) in the silicon oxide film is composed of Si, SiO, SiO₂, and so forth, and the ratios thereamong will vary with the process conditions. A preferred range for the value of x in the silicon oxide (SiOₓ) is x=0.1 to 2, and x=2 gives silicon dioxide (SiO₂).

Viewed from the standpoint of the gas barrier properties, the thickness of the silicon oxide layer, that is, silicon oxide film on the fiber-reinforced film made of a cured organopolysiloxane resin is preferably 5 to 800 nm and more preferably 70 to 500 nm.

The silicon oxide layer, that is, silicon oxide film may be formed on one side or on both sides of the fiber-reinforced film made of a cured organopolysiloxane resin. Moreover, the vapor deposition process, that is, film formation process may be carried out a plurality of times.

A cured organopolysiloxane resin film having gas barrier properties according to claim 11 as the third invention of the present application is characterized by comprising a fiber-reinforced film made of a cured organopolysiloxane resin which is transparent in the visible region and obtained by a crosslinking reaction between

(A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film,
wherein a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane,
is interposed between the aforementioned fiber-reinforced film and the aforementioned transparent inorganic layer,
a cured polymer layer is formed on the aforementioned transparent inorganic layer, and a transparent inorganic layer selected from the group consisting of a silicon oxynitride layer, silicon nitride layer, and silicon oxide layer is formed on the aforementioned cured polymer layer.
The cured organopolysiloxane resin film having gas barrier properties according to claim 11 can be expressed as follows:
A cured organopolysiloxane resin film having gas barrier properties characterized in that
a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is formed on a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst;
a transparent inorganic layer selected from the group consisting of a silicon oxynitride layer, silicon nitride layer, and silicon oxide layer is formed on the aforementioned cured organopolysiloxane layer;
a cured polymer layer is formed on the aforementioned transparent inorganic layer; and a transparent inorganic layer selected from the group consisting of a silicon oxynitride layer, silicon nitride layer, and silicon oxide layer is formed on the aforementioned cured polymer layer.

In the cured organopolysiloxane resin film having gas barrier properties according to claim 11, it is preferable that the cured polymer is a ultraviolet ray-cured polymer, electron beam-cured polymer, or heat-cured polymer, and the fiber reinforcement in the fiber-reinforced film comprises an inorganic fiber or synthetic fiber, and is in the form of a single fiber, thread, woven cloth or non-woven cloth.

The cured organopolysiloxane resin film having gas barrier properties according to claim 11 can be produced by

(I) forming a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane, by coating, on a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst;
(II) forming a transparent inorganic layer selected from the group consisting of a silicon oxynitride layer, silicon nitride layer, and silicon oxide layer, by vapor deposition, on the aforementioned cured organopolysiloxane layer;
(III) forming a cured polymer layer, by coating, on the transparent inorganic layer; and then
(IV) forming a transparent inorganic layer selected from the group consisting of a silicon oxynitride layer, silicon nitride layer, and silicon oxide layer, by vapor deposition, on the aforementioned cured polymer layer.

In the aforementioned method of producing a cured organopolysiloxane resin film having gas barrier properties, it is preferable that the cured organopolysiloxane layer (a), the cured organopolysiloxane layer (b), and the cured organopolysiloxane layer (c) is formed by a condensation reaction or hydrosilylation reaction, the cured organopolysiloxane layer (d) is formed by polymerization between polymerizable organic functional groups by means of high energy ray irradiation or actinic energy ray irradiation or heating, the cured organopolysiloxane layer (e) is formed by a condensation reaction or hydrosilylation reaction and by polymerization between polymerizable organic functional groups by means of high energy ray irradiation or actinic energy ray irradiation or heating,

and the cured polymer layer is formed by irradiating ultraviolet ray on a ultraviolet ray-curable monomer, oligomer or polymer in the presence of a photopolymerization initiator, irradiating electron beam on an electron beam-curable monomer, oligomer or polymer, or heating a heat-curable monomer, oligomer or polymer.

The cured organopolysiloxane resin film having gas barrier properties according to claim 15 as the fourth invention of the present application is characterized by comprising a fiber-reinforced film made of a cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a silicon oxynitride layer that is formed on the aforementioned fiber-reinforced film, wherein a molar ratio of hydrosilyl groups of component (B) to unsaturated aliphatic hydrocarbyls of component (A) is within the range of 1.05 to 1.50, and the cured organopolysiloxane resin has hydrosilyl groups, a cured polymer layer is formed on the aforementioned silicon oxynitride layer, and a silicon oxynitride layer is formed on the aforementioned cured polymer layer.

In the cured organopolysiloxane resin film having gas barrier properties according to claim 15, it is preferable that the cured polymer is an ultraviolet ray-cured polymer, electron beam-cured polymer, or heat-cured polymer, the fiber reinforcement in the fiber-reinforced film comprises an inorganic fiber or synthetic fiber, and is in the form of a single fiber, thread, woven cloth or non-woven cloth.

The cured organopolysiloxane resin film having gas barrier properties according to claim 15 is characterized by further forming a cured polymer layer on the silicon oxynitride layer, and forming a silicon oxynitride layer on the cured polymer layer in comparison with the cured organopolysiloxane resin film having gas barrier properties according to claim 9.

The cured organopolysiloxane resin film having gas barrier properties according to claim 15 as the fourth invention of the present application can be manufactured by

(I) forming a silicon oxynitride layer, by ion plating, on a fiber-reinforced film made of a hydrosilyl group-containing cured organopolysiloxane resin which is transparent in the visible region and obtained by a crosslinking reaction between (A) an organopolysiloxane resin that is represented by the average siloxane unit formula

RₐSiO_{(4-a)/2} (1)

wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst,
(II) forming a cured polymer layer, by coating, on the aforementioned silicon oxynitride layer, and then
(III) forming a silicon oxynitride layer, by ion plating, on the cured polymer layer.
(II) forming a cured polymer layer, by coating, on the aforementioned silicon oxynitride layer, and then
(III) forming a silicon oxynitride layer, by ion plating, on the aforementioned cured polymer layer (see claim 17).

The method of producing the cured organopolysiloxane resin film having gas barrier properties according to claim 17 is characterized by further forming a cured polymer layer on the silicon oxynitride layer, and forming a silicon oxynitride layer on the cured polymer layer in comparison with the method of producing the cured organopolysiloxane resin film having gas barrier properties according to claim 10.

The monomer, oligomer or polymer which is a precursor of the cured polymer, used in the process of claim 13 and claim 17, is not specifically restricted provided that it is possible to be coated thinly, it can be easily cured by a polymerization reaction or cross-linking reaction, and it adheres well to the transparent inorganic layer selected from the group consisting of a silicon oxynitride layer, silicon nitride layer, or silicon oxide layer.

Examples of such curable monomer, oligomer or polymer include an ultraviolet ray-curable monomer, oligomer or polymer which is a precursor of the ultraviolet ray-cured polymer, an electron beam-curable monomer, oligomer or polymer which is a precursor of an electron beam-cured polymer, and a heat-curable monomer, oligomer or polymer which is a precursor of a heat-cured polymer.

The cured polymer is preferably a cured oxygen-containing organic polymer, more preferably a cured organic polymer consisting of carbon atoms, hydrogen atoms and oxygen atoms and a cured organic polymer consisting of carbon atoms, hydrogen atoms, oxygen atoms and nitrogen atoms from the standpoint of the adhesiveness to silicon oxynitride layer, that is, silicon oxynitride film, silicon nitride layer, that is, silicon nitride film, or silicon oxide layer that is silicon oxide film, and the adhesiveness of a silicon oxynitride layer, that is, silicon oxynitride film, silicon nitride layer, that is, silicon nitride film, or silicon oxide layer that is silicon oxide film to the cured polymer. The cured oxygen-containing organic polymer preferably contains a carbonyl group, or a polar bond such as carboxylic acid ester bond, carboxylic acid amide bond, ether bond (C—O—C) and so forth.

A monomer, oligomer or polymer which contains one or more ethylenic unsaturated double bonds per molecule or a monomer, oligomer or polymer which contains one or more cationic polymerizable groups per molecule is exemplified as an ultraviolet ray-curable monomer, oligomer or polymer which is a precursor of the ultraviolet ray-cured polymer.

The monomer, oligomer or polymer which contains one or more ethylenic unsaturated double bonds per molecule is radical-polymerizable.

Preferable monomer, oligomer or polymer which contains one or more ethylenic unsaturated double bonds per molecule is a radical-polymerizable acrylate compound or methacrylate compound.
Examples of the radical-polymerizable acrylate compound or methacrylate compound include an alkyleneoxide-modified acrylate or methacrylate obtained by reacting an adduct of ethylene oxide or propylene oxide to an alcohol and acrylic acid, methacrylic acid or polymer thereof; a carboxyalkylester-modified acrylate or methacrylate obtained by reacting an alcohol and a carboxyalkyl acrylate or methacrylate; epoxy-modified acrylate or methacrylate obtained by reacting acrylic acid, methacrylic acid or polymer thereof with an epoxy group of a glycidylether of an alcohol; an urethane bond-containing acrylate or methacrylate obtained by reacting a hydroxyl group-containing acrylate or methacrylate and a compound having isocyanate group at the molecular terminal; and a mixture of the preceeding;

an acrylate or methacrylate-modified epoxy resin obtained by reacting acrylic acid, methacrylic acid or polymer thereof with an epoxy resin; an acrylate or methacrylate-modified epoxy resin obtained by reacting acrylic acid, methacrylic acid or polymer thereof with an alkyleneoxide-modified or carboxyalkyl-modified epoxy resin; a prepolymer or polymer of an urethane bond-containing acrylate or methacrylate obtained by reacting a hydroxyl group-containing acrylate or methacrylate and a compound having isocyanate group; an acrylate or methacrylate-modified polyester obtained by reacting acrylic acid, methacrylic acid or polymer thereof with a polyester; a mixture of the preceding;

further an unsaturated polyester resin, and an acryl- or methacryl-modified silicone resin or polysiloxane. The aforementioned organopolysiloxane having an acryloxy-functional group or acrylamide-functional group (see paragraph [0156]) is exemplified as the acryl or methacryl-modified organopolysiloxane resin or polysiloxane. Examples of a resin, oligomer or polymer which contains one or more cationic polymerizable groups per molecule include an epoxy resin, oxetanyl resin, epoxy-modified polyacrylate resin, epoxy-modified polymethacrylate resin, and epoxy-modified silicone resin or polysiloxane.

A small amount of a photo-polymerization initiator is usually added to the ultraviolet ray-curable monomer, oligomer or polymer which is a precursor of the ultraviolet ray-cured polymer in order to make it ultraviolet ray-curable. Examples of the photo-polymerization initiator include acetophenon, benzophenon, thioxhanton, benzoin, benzoin methyl ether, benzoylbenzoate, Michelar ketone, diphenylsulfide, dibenzyl disulfide, triphenylbiimidazole, isopropyl-N,N-dimethylaminobenzoate.

It is preferable to incorporate further a photo-sentisizer which is exemplified by n-butylamine, triethylamine, and poly-n-butylphosphine. The photo-polymerization initiator or photo-sentisizer is incorporated preferably at about 0.1 to 10 parts by weight per 100 parts by weight of the ultraviolet ray-curable monomer, oligomer or polymer which is a precursor of the ultraviolet ray-cured polymer.

The electron beam-curable monomer, oligomer or polymer which is a precursor of an electron beam-cured polymer contains one or more ethylenic unsaturated double bonds per molecule and is radical-polymerizable. The aforementioned radical-polymerizable acrylate compound or methacrylate compound is preferable. An unsaturated polyester resin and an acryl- or methacryl-modified silicone resin or polysiloxane are exemplified. The aforementioned organopolysiloxane having an acryloxy-functional group or acrylamide-functional group is exemplified as the acryl- or methacryl-modified silicone resin or polysiloxane (see paragraph [0156]).

An ultraviolet ray-curable resin and electron beam-curable resin are a kind of ionizing radiation-curable resins. Other ionizing radiation-curable resins can be employed as the curable polymer.

Examples of the heat-curable monomer, oligomer or polymer which is a precursor of a heat-cured polymer include a thermosetting acylic resin such as glycidyl group-containing acylic copolymer, hydroxyl group-containing acylic copolymer, carboxylic group-containing acylic copolymer; epoxy resin such as bisphenol A-type epoxy resin, bisphenol F type-epoxy resin, cycloaliphatic epoxy resin, glycidylester-type epoxy resin, glycidylamine-type epoxy resin, biphenyl-type epoxy resin; epoxy-modified polyamide resin, thermosetting polyurethane resin, unsaturated polyester resin, amino resin such as urea resin and melamine resin, phenol resin, maleimide resin, and thermosetting silicone resin such as condensation reaction-curable organopolysiloxane resin, hydrosilylation reaction-curable organopolysiloxane resin, and hydrosilylation reaction-curable diorganopolysiloxane, where the thermosetting acylic resin, thermosetting epoxy resin, and silicone resin are preferable.

A cross-linking agent and/or curing catalyst are usually incorporated to the afore-mentioned thermosetting resin to cure it. According to need, a curing promoter, curing retarder, adhesion promoter such as a silane coupling agent can be incorporated.

When the aforementioned curable monomer, oligomer or polymer which is a precursor of cured polymer is a liquid with high viscosity or solid at ambient temperature, it is preferably rendered coatable as a thin film by dissolution in an organic solvent.

Organic solvents which easily evaporate under heating at 200° C. or less are preferable. Examples of preferred organic solvents are ketones such as acetone, methylethylketone, methyl isobutyl ketone, and so forth; aromatic hydrocarbons such as toluene, xylene, and so forth; aliphatic hydrocarbons such as heptane, hexane, octane, and so forth; ethers such as THF, dioxane and so forth; as well as dimethylformamide and N-methylpyrrolidone.

These organic solvents are used in an amount to solve the aforementioned curable monomer, oligomer or polymer which is a precursor of cured polymer and to enable the resulting solution to be coated as a thin film.

Once coating on the silicon oxynitride layer, that is, silicon oxynitride film, silicon nitride layer, that is, silicon nitride film, or silicon oxide layer that is silicon oxide film has been carried out, curing is preferably effected after the organic solvent has been evaporated off by heating at low temperature or by exposure to a hot air current.

Processes for coating the aforementioned curable monomer, oligomer or polymer which is a precursor of cured polymer on the silicon oxynitride layer, that is, silicon oxynitride film, silicon nitride layer, that is, silicon nitride film, or silicon oxide layer, that is, silicon oxide film include various ones according to objects. Examples of the coating method include spraying, roller coating, brush application, blade coating, casting, spin coating, screen printing, off-set printing, gravure printing, and relief printing.

Suitable sources for curing the aforementioned ultraviolet ray-curable monomer, oligomer or polymer which is a precursor of ultraviolet ray-cured polymer are ultra high pressure mercury lamps, high pressure mercury lamps, low pressure mercury lamps, xenon lamps, carbon arc lamps, metalhalide lamps and the like. The ultraviolet radiation is provided at a wavelength of preferably 190 to about 380 nm. The ultraviolet ray is irradiated in a sufficient dose to cure the aforementioned ultraviolet ray-curable monomer, oligomer or polymer which is a precursor of cured polymer. Preferable dose of ultraviolet rays is 100 to 10,000 mJ/cm² or less, and more preferable dose of ultraviolet rays is 800 to 2,000 mJ/cm².

Heating can follow after the ultraviolet ray irradiation.

Examples of electron beam sources include Cockkroftwalt type, Bandegraft type, resonance transformer type, insulation core transformer type; linear type, Dynamitron type, high frequency type, and other electron beam accelerators.

Electron beam is irradiated in a sufficient dose to cure the aforementioned electron beam-curable monomer, oligomer or polymer which is a precursor of electron beam-cured polymer.
The aforementioned electron beam-curable monomer, oligomer or polymer is irradiated with electron beam radiation preferably at 8 to 30 megarads in an inert atmosphere. Heating can follow after the electron beam irradiation.

Hot air blowing, infrared light irradiation and far infrared light irradiation are exemplified as methods for curing the heat-curable monomer, oligomer or polymer which is a precursor of a heat-cured polymer.

A method for forming a transparent inorganic layer selected from the group consisting of a silicon oxynitride layer, silicon nitride layer, and silicon oxide layer on the aforementioned cured polymer layer conforms to the method for forming a transparent inorganic layer selected from the group consisting of a silicon oxynitride layer, silicon nitride layer, and silicon oxide layer on the aforementioned fiber-reinforced film made of a cured organopolysiloxane resin.

### EXAMPLES

The weight-average molecular weight and the molecular weight distribution of the methylphenylvinylpolysiloxane resins in the synthesis examples were measured with the use of gel permeation chromatography, that is, GPC. The GPC instrument used for this purpose comprised HLC-8020GPC of Tosoh Corporation which was equipped with a refractive index detector and two TSKgeI GMHXL-L columns which is a product of TOSOH Corporation). The sample materials were submitted to measurement of the elution curve as the 2 weight % chloroform solution. The calibration curve was constructed using polystyrene standards of known weight-average molecular weight. The weight-average molecular weight was determined with reference to polystyrene standards.

The water vapor transmission rate of the glass fiber-reinforced film made of the cured organopolysiloxane resin per se and the glass fiber-reinforced film made of the cured organopolysiloxane resin having a silicon oxynitride layer, i.e., silicon oxynitride film was measured by the Mocon method using a Mocon Permatran-W3-31 instrument for measuring water vapor transmission.

200 g of phenyltrimethoxysilane, 38.7 g of tetramethyldivinyldisiloxane, 65.5 g of deionized water, 256 g of toluene, and 1.7 g of trifluoromethanesulfonic acid were combined in a 3-necks, round-bottom flask equipped with a Dean-Stark Trap and a thermometer. The mixture was heated at 60 to 65° C. for 2 hours. The mixture was then heated to reflux and water and methanol were removed using a Dean-Stark trap. When the temperature of the mixture reached 80° C. and the removal of water and methanol was complete, the mixture was cooled to less than 50° C. 3.3 g of calcium carbonate and about 1 g of water were added to the mixture. The mixture was stirred at room temperature for 2 hours and then 0.17 g of potassium hydroxide was added to the mixture. The mixture was then heated to reflux and water was removed using a Dean-Stark trap. When the reaction temperature reached 120° C. and the removal of water was complete, the mixture was cooled to less than 40° C.

0.37 g of chlorodimethylvinylsilane was added to the cooled mixture and mixing was continued at room temperature for 1 hour. The mixture was filtered to give a toluene solution of a methylphenylvinylpolysiloxane resin having the average siloxane formula: (PhSiO_{3/2})_{0.75}(ViMe₂SiO_{1/2})_{0.25} in toluene. The resin has a weight-average molecular weight of about 1700, has a number-average molecular weight of about 1440, and contains about 1 mole % of silicon-bonded hydroxy groups.

The volume of the toluene solution was adjusted to produce a solution containing 79.5 percent by weight of the methylphenylvinylpolysiloxane resin in toluene. The resin concentration of the toluene solution was determined by measuring the weight loss after drying 2.0 g of sample of the toluene solution in an oven at 150° C. for 1.5 hours.

### Reference Example

### Preparation of the Glass Fiber-Reinforced Film Made of the Cured Methylphenylvinylpolysiloxane Resin

The methylphenylvinylpolysiloxane resin solution of Synthesis Example 1 and 1,4-bis(dimethylsilyl)benzene were introduced into a 3-necks round bottom flask equipped with a Deanstark trap and a thermometer, wherein the relative amount of the two ingredients was sufficient to achieve a mole ratio of silicon-bonded hydrogen atoms to silicon-bonded vinyl groups (SiH/SiVi) of 1.1:1, as determined by ²⁹Si NMR and ¹³C NMR. The mixture was heated at 80° C. under a pressure of 667 Pa, that is, 5 mmHg to remove the toluene.

Then, a small amount of 1,4-bis(dimethylsilyl)benzene was added to the toluene-removed mixture to restore the mole ratio SiH/SiVi to 1.1:1. To the mixture was added 0.5% w/w, based on the weight of the resin, of a platinum catalyst containing 1000 ppm of platinum to form a hydrosilylation reaction-curable methylphenylvinylpolysiloxane resin composition. This platinum catalyst is 1,1,3,3-tetramethyldisiloxane solution of a platinum(0)-1,1,3,3-tetramethyldisiloxane complex.

A flat glass plate (a width of 25.4 cm and a length of 38.1 cm) was covered with a first Nylon® film (IPPLON® WN1500 Vacuum Bagging Film manufactured by International Plastic Products, Inc., of Carson, Calif.) to form a release liner. The aforementioned hydrosilylation reaction-curable methylphenylvinylpolysiloxane resin composition was uniformly applied to the Nylon film using a No. 16 Mylar® metering rod to form a methylphenylvinylpolysiloxane resin composition film. A unfinished plain glass cloth (a product of JPS Glass (Slater, S.C.), type 106 electric glass cloth with a thickness of 37.5 μm) having the same dimensions as the Nylon film was carefully laid down on the coated methylphenylvinylpolysiloxane resin composition, allowing sufficient time for the composition to thoroughly wet the cloth. The embedded cloth was then degassed under vacuum (5.3 kPa) at room temperature for 0.5 hour.

The methylphenylvinylpolysiloxane resin composition was then uniformly applied to the degassed embedded cloth, and the degassing procedure was repeated. The impregnated glass cloth was covered with a second Nylon® film (IPPLON® WN1500 Vacuum Bagging Film manufactured by International Plastic Products, Inc., of Carson, Calif.) and the resulting composite was compressed with a stainless steel roller to drive out air bubbles and excess hydrosilylation reaction-curable methylphenylvinylpolysiloxane resin composition.

The composite was heated in an air-forced oven under an applied pressure (external weight) of 22. 2 N according to the following cycle: room temperature to 100° C. at 1° C./min., 100° C. for 2 hours; 100° C. to 160° C. at 1° C./min., 160° C. for 2 hours; and 160° C. to 200° C. at 1° C./min., 200° C. for 1 hour. The oven was turned off and the composite was allowed to cool to room temperature.

The mole ratio of silicon-bonded hydrogen atoms to silicon-bonded vinyl groups (SiH/SiVi) was 1.0:1.0 after heated since the 1,4-bis(dimethylsilyl)benzene was easy to evaporate.

The glass fiber-reinforced film (A) made of the cured methylphenylvinylpolysiloxane resin was separated from the Nylon films. The reinforced film had a uniform thickness (0.07 mm) and was substantially transparent and free of voids. The mechanical properties of the glass fiber-reinforced film (A) made of the cured methylphenylvinylpolysiloxane resin are shown in Table 1.

A glass fiber-reinforced film (B) made of the cured methylphenylvinylpolysiloxane resin was prepared according to the method of Reference Example, except the first Nylon® film was replaced with a glass plate. Prior to use, the glass plate was treated with Relisse® 2520 release gel to render the surface hydrophobic, and the treated glass was then washed in mild aqueous detergent and rinsed with water to remove excess gel. The Relisse® 2520-treated glass surface released very easily from the glass fiber-reinforced made of the cured methylphenylvinylpolysiloxane resin. The corresponding surface of the reinforced film was smooth, similar to the surface of the glass plate. The mechanical properties of the glass fiber-reinforced film made of the cured methylphenylvinylpolysiloxane resin are shown in Table 1.

TABLE 1

| | | | | Young's Modulus | | Strain at Break | |
|---|---|---|---|---|---|---|---|
| | Thickness | Tensile Strength (MPa) | | (GPa) | | (%) | |
| | (mm) | Warp | Fill | Warp | Fill | Warp | Fill |
| (A) | 0.07 | 162.1 ± 6.4 | — | 11.12 ± 0.24 | — | 1.7 ± 0.1 | — |
| (B) | 0.06 | 121.9 ± 21.0 | 123.8 ± 12.3 | 3.27 ± 0.32 | 2.55 ± 0.28 | 4.8 ± 1.0 | 5.4 ± 0.9 |

— denotes value not measured.

### Synthesis Example 2

80 g of toluene, 49.7 g of 3-methacryloxypropyltrimethoxysilane, 79.3 g of phenyltrimethoxysilane, 1 g of a 50 weight % aqueous solution of cesium hydroxide, 200 g of methanol, and 40 mg of 2,6-di-t-butyl-4-methylphenol were introduced into a 3-necks round bottom flask equipped with a Deanstark trap and a thermometer, and heated under reflux for 1 hour while stirring. During this interval, 250 g of methanol was removed by distillation and the same amount of toluene was simultaneously added. After the removal of almost all the methanol and water, heating to 105° C. was carried out over about 1 hour. After cooling to room temperature, additional toluene was added to give the approximately 15 weight % solution, and 3 g of acetic acid was added and stirring was carried out for 30 minutes. The resulting toluene solution was washed with water and filtered across a membrane filter with a pore diameter of 1 μm to remove the cesium hydroxide. The toluene was then removed from the filtrate under reduced pressure.

40 g of the poly(phenyl-co-3-methacryloxypropyl)silsesquioxane thus obtained was dissolved in 60 g of propylene glycol monoethyl ether acetate. To this solution was added Irgacure® 819 which is a photocure initiator and a product of Ciba Specialty Chemicals at 3 weight % of the silsesquioxane, thus yielding a coating solution.

### Example 1

The coating solution obtained in the Synthesis Example 2 was spin-coated for 30 seconds at 2500 rpm on one side of the glass fiber-reinforced film (A) made of the cured methylphenylvinylpolysiloxane resin with a width of 10 cm, a length of 10 cm, and a thickness of 100 μm which was obtained in the aforementioned Reference Example. The 3-methacryloxy groups of the poly(phenyl-co-3-methacryloxypropyl)silsesquioxane were polymerized with each other by exposing the coated side for 15 minutes to ultraviolet radiation where exposure dose was 30 mW/cm² using a 200 W Hg—Xe lamp, and this was followed by holding for 120 minutes at 150° C. to cure the poly(phenyl-co-3-methacryloxypropyl)silsesquioxane.

On the cured poly(phenyl-co-3-methacryloxypropyl)silsesquioxane layer was formed a silicon oxynitride layer, that is, silicon oxynitride film with a thickness of 30 nm by ion plating.

A silicon oxide rod was employed as a film-formation material, N₂ gas was employed as a reactive gas, argon gas was employed as a carrier gas, the discharge current was 120 A, and the pressure during film formation was 0.67 Pa, that is, 5 mTorr, the substrate temperature was room temperature, and the cycle time was once. According to visual observation, the silicon oxynitride layer, that is, silicon oxynitride film was uniform and free of peeling.

This glass fiber-reinforced film made of the cured methylphenylvinylpolysiloxane resin having the silicon oxynitride layer, that is, silicon oxynitride film was transparent in the visible light region, and its water vapor transmission rate was 0.44 g/m²·day.

### Comparative Example 1

On one side of the glass fiber-reinforced film (A) made of the cured methylphenylvinylpolysiloxane resin with a width of 10 cm, a length of 10 cm, and a thickness of 100 μm which was obtained in the aforementioned Reference Example was formed a silicon oxynitride layer, that is, silicon oxynitride film with a thickness of 50 nm by ion plating.

This glass fiber-reinforced film made of the cured methylphenylvinylpolysiloxane resin having the silicon oxynitride layer, that is, silicon oxynitride film was transparent in the visible light region, and had a water vapor transmission rate of 4.29 g/m²·day.

### Example 2

In the same as in Example 1, the coating solution obtained in the Synthesis Example 2 was spin coated for 30 seconds at 2500 rpm on one side of the glass fiber-reinforced film (A) made of the cured methylphenylvinylpolysiloxane resin with a width of 10 cm, a length of 10 cm, and a thickness of 100 μm which was obtained in the aforementioned Reference Example, the coated side was exposed to ultraviolet radiation for 15 seconds using a 1.5 kW UV lamp, and this was followed by holding for 120 minutes at 150° C. to cure the poly(phenyl-co-3-methacryloxypropyl)silsesquioxane.

In the same condition as in Example 1, a silicon oxynitride layer, that is, silicon oxynitride film with a thickness of 30 nm was formed by ion plating.

A coating agent comprising a radical-type ultraviolet ray-curable organic resin (from DIC, product name is DAICURE® Clear SD347) was spin-coated on the silicon oxynitride layer, that is, silicon oxynitride film. The coated coating agent had a thickness of 5 μm. The coated side was exposed to ultraviolet radiation for 15 seconds where exposure dose using a 1.5 kW UV lamp, and a silicon oxynitride layer, that is, silicon oxynitride film with a thickness of 30 nm was formed on the cured coating agent by ion plating.

This glass fiber-reinforced film made of the cured organopolysiloxane resin having the double silicon oxynitride layers, that is, silicon oxynitride films was transparent in the visible light region, and its water vapor transmission rate was 0.013 to 0.020 g/m²·day.

### Example 3

In the same way as in Example 2, the coating solution obtained in the Synthesis Example 2 was spin-coated for 30 seconds at 2500 rpm on one side of the glass fiber-reinforced film made (A) of the cured methylphenylvinylpolysiloxane resin with a width of 10 cm, a length of 10 cm, and a thickness of 100 μm which was obtained in the aforementioned Reference Example, the coated side was exposed to ultraviolet radiation for 15 seconds using a 1.5 kW UV lamp, and this was followed by holding for 120 minutes at 150° C. to cure the poly(phenyl-co-3-methacryloxypropyl)silsesquioxane.

In the same condition as in Example 1, a silicon oxynitride layer, that is, silicon oxynitride film with a thickness of 30 nm was formed by ion plating.

A coating solution obtained in the Synthesis Example 2 was spin-coated for 5 minutes at 800 rpm and for 20 minutes at 3500 rpm on the silicon oxynitride layer, that is, silicon oxynitride film. The coated side was exposed to ultraviolet radiation for 15 seconds using a 1.5 kW UV lamp to cure poly(phenyl-co-3-methacryloxypropyl)silsesquioxane, and a silicon oxynitride layer, that is, silicon oxynitride film with a thickness of 30 nm was formed on the cured poly(phenyl-co-3-methacryloxypropyl)silsesquioxane with a thickness of 1.5 μm by ion plating in the same condition as in Example 1.

This glass fiber-reinforced film made of the cured organopolysiloxane resin having the double silicon oxynitride layers, that is, silicon oxynitride films was transparent in the visible light region, and its water vapor transmission rate was 0.038 to 0.109 g/m²·day.

### Example 4

Then, the methylphenylvinylpolysiloxane resin represented by the average siloxane unit formula: (PhSiO_{3/2})_{0.75}(Me₂SiO_{1/2})_{0.25} in Synthesis Example 1 and methylphenylhydrogenpolysiloxane resin represented by the average siloxane unit formula: (HMe₂ SiO_{1/2})_{0.60}(PhSiO_{3/2})_{0.40} were blended in a weight ratio to provide a mole ratio of silicon-bonded hydrogen atoms in the latter to silicon-bonded vinyl groups in the former to 1.2:1, and were thoroughly stirred.

To the polysiloxane resin mixture was added 1,1,3,3-tetramethyldisiloxane solution of a platinum-1,1,3,3-tetramethyldisiloxane complex containing 5% by weight of platinum in a quantity of 2 ppm calculated as the weight of the metallic platinum relative to the combined weight of the aforementioned polysiloxane resin mixture to yield a liquid hydrosilylation reaction-curable methylphenylvinylpolysiloxane resin composition of which solid content was 100% by weight.

This liquid hydrosilylation reaction-curable methylphenylvinylpolysiloxane resin composition was spin-coated for 30 seconds at 2500 rpm on one side of the glass fiber-reinforced film (A) made of the cured methylphenylvinylpolysiloxane resin with a width of 10 cm, a length of 10 cm, and a thickness of 100 μm which was obtained in the aforementioned Reference Example, and the coated composition was heated for 2 hours at 150° C. to cure it.

In the same condition as in Example 1, a silicon oxynitride layer, that is, silicon oxynitride film with a thickness of 30 nm was formed on the cured methylphenylvinylpolysiloxane resin layer by ion plating.

A coating agent comprising a radical-type ultraviolet ray-curable organic resin (from DIC, product name is DAICURE® Clear SD347) was spin-coated on the silicon oxynitride layer, that is, silicon oxynitride film. The coated coating agent had a thickness of 5 μm. The coated side was exposed to ultraviolet radiation for 15 seconds using a 1.5 kW UV lamp to cure the coated coating agent, and a silicon oxynitride layer, that is, silicon oxynitride film with a thickness of 30 nm was formed on the cured coating agent by ion plating in the same condition as in Example 1.
This glass fiber-reinforced film made of the cured organopolysiloxane resin having the double silicon oxynitride layers, that is, silicon oxynitride films was transparent in the visible light region, and its water vapor transmission rate was 0.0026 to 0.0225 g/m²·day.

### Comparative Example 2

In the same condition as in Example 1, a silicon oxynitride layer, that is, silicon oxynitride film with a thickness of 30 nm was formed by ion plating on one side of the glass fiber-reinforced film (A) made of the cured methylphenylvinylpolysiloxane resin with a width of 10 cm, a length of 10 cm, and a thickness of 100 μm which was obtained in the aforementioned Reference Example.

A coating agent comprising a radical-type ultraviolet ray-curable organic resin (from DIC, product name is Daicure® Clear SD347) was spin-coated on the silicon oxynitride layer, that is, silicon oxynitride film. The coated coating agent had a thickness of 5 μm. The coated side was exposed to ultraviolet radiation for 15 seconds using a 1.5 kW UV lamp to cure the coated coating agent, and a silicon oxynitride layer, that is, silicon oxynitride film with a thickness of 30 nm was formed on the cured coating agent by ion plating in the same condition as in Example 1.
This glass fiber-reinforced film made of a cured organopolysiloxane resin having the double silicon oxynitride layers, that is, silicon oxynitride films was transparent in the visible light region, and its water vapor transmission rate was 20 g/m²·day.

### INDUSTRIAL APPLICABILITY

The cured organopolysiloxane resin film having gas barrier properties of the present invention is useful as a film substrate for the transparent electrodes in electroluminescent displays, liquid-crystal displays, and so forth; as a back sheet for crystalline silicon solar cells; and as a substrate for amorphous silicon solar cells.

The inventive method of producing the cured organopolysiloxane resin film having gas barrier properties is useful for the facile and precise production of the cured organopolysiloxane resin film having gas barrier properties.

### DESCRIPTION OF THE REFERENCE SYMBOLS

1: glass fiber-reinforced film made of the cured organopolysiloxane resin
2: organic functional group-containing cured organopolysiloxane layer
3: silicon oxynitride layer
4: glass cloth

1. A cured organopolysiloxane resin film having gas barrier properties, the cured organopolysiloxane resin film comprising a fiber-reinforced film made of a cured organopolysiloxane resin which is transparent in the visible region and obtained by a crosslinking reaction between
(A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein
a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane
is interposed between the fiber-reinforced film and the transparent inorganic layer.

2. The cured organopolysiloxane resin film having gas barrier properties according to claim 1, wherein the organic functional group is an oxygen-containing organic functional group, the polymerizable organic functional group is a polymerizable oxygen-containing organic functional group, and the organic group is an oxygen-containing organic group.

3. The cured organopolysiloxane resin film having gas barrier properties according to claim 2, wherein the oxygen-containing organic functional group is an acryloxy functional group, epoxy functional group, or oxetanyl functional group, the polymerizable organic functional group is an acryloxy functional group, epoxy functional group, oxetanyl functional group or alkenylether functional group, and the oxygen-containing organic group has a carbonyl group or C—O—C linkage.

4. The cured organopolysiloxane resin film having gas barrier properties according to claim 3, wherein the acryloxy functional group is an acryloxyalkyl group or methacryloxyalkyl group and the epoxy functional group is a glycidoxyalkyl group or epoxycyclohexylalkyl group.

5. The cured organopolysiloxane resin film having gas barrier properties according to claim 1, wherein the fiber reinforcement in the fiber-reinforced film comprises an inorganic fiber or synthetic fiber.

6. The cured organopolysiloxane resin film having gas barrier properties according to claim 1, wherein the fiber reinforcement is in the form of a single fiber, yarn, woven cloth or non-woven cloth.

7. A method of producing the cured organopolysiloxane resin film having gas barrier properties according to claim 1, the method comprising
(I) forming a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane,
by coating, on a fiber-reinforced film made of a cured organopolysiloxane resin which is transparent in the visible region and obtained by a crosslinking reaction between (A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst; and then
(II) forming a transparent inorganic layer selected from the group consisting of a silicon oxynitride layer, silicon nitride layer, and silicon oxide layer, by vapor deposition, on the cured organopolysiloxane layer.

8. The method of producing a cured organopolysiloxane resin film having gas barrier properties according to claim 7, wherein the cured organopolysiloxane layer (a), the cured organopolysiloxane layer (b) and the cured organopolysiloxane layer (c) are formed by a condensation reaction or hydrosilylation reaction, the cured organopolysiloxane layer (d) is formed by polymerization between polymerizable organic functional groups by means of high energy ray irradiation or actinic energy ray irradiation or heating, and the cured organopolysiloxane layer (e) is formed by a condensation reaction or hydrosilylation reaction and by polymerization between polymerizable organic functional groups by means of high energy ray irradiation or actinic energy ray irradiation or heating.

9. A cured organopolysiloxane resin film having gas barrier properties, the cured organopolysiloxane resin film comprising a fiber-reinforced film made of a cured organopolysiloxane resin which is transparent in the visible region and obtained by a crosslinking reaction between (A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a silicon oxynitride layer that is formed on the fiber-reinforced film,
wherein a molar ratio of hydrosilyl groups of component (B) to unsaturated aliphatic hydrocarbyls of component (A) is within the range of 1.05 to 1.50, and the cured organopolysiloxane resin has hydrosilyl groups.

10. A method of producing the cured organopolysiloxane resin film having gas barrier properties according to claim 9, the method comprising forming a silicon oxynitride layer, by reactive ion plating, on a fiber-reinforced film made of a hydrosilyl group-containing cured organopolysiloxane resin which is transparent in the visible region and obtained by a crosslinking reaction between (A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst.

11. A cured organopolysiloxane resin film having gas barrier properties, the cured organopolysiloxane film comprising a fiber-reinforced film made of a cured organopolysiloxane resin which is transparent in the visible region and obtained by a crosslinking reaction between
(A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a transparent inorganic layer selected from the group consisting of a silicon oxynitride layer, silicon nitride layer, and silicon oxide layer that is formed on the fiber-reinforced film, wherein a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane,
is interposed between the fiber-reinforced film and the transparent inorganic layer,
a cured polymer layer is formed on the transparent inorganic layer, and a transparent inorganic layer selected from the group consisting of a silicon oxynitride layer, silicon nitride layer, and silicon oxide layer is formed on the cured polymer layer.

12. A cured organopolysiloxane resin film having gas barrier properties according to claim 11, wherein the cured polymer is a ultraviolet ray-cured polymer, electron beam-cured polymer, or heat-cured polymer, and the fiber reinforcement in the fiber-reinforced film comprises an inorganic fiber or synthetic fiber, and is in the form of a single fiber, thread, woven cloth or non-woven cloth.

13. A method of producing the cured organopolysiloxane resin film having gas barrier properties according to claim 11, the method comprising
(I) forming a cured organopolysiloxane layer selected from the group consisting of
(a) an organic functional group-containing cured organopolysiloxane layer,
(b) a silanol group-containing cured organopolysiloxane layer free from the organic functional group,
(c) a hydrosilyl group-containing cured organopolysiloxane layer free from the organic functional group,
(d) a layer of cured organopolysiloxane having organic groups produced by polymerization between polymerizable organic functional groups of an organopolysiloxane having two or more polymerizable organic functional groups in one molecule, and
(e) a cured organopolysiloxane layer formed by polymerizing the polymerizable organic functional groups with each other and reacting the crosslinking groups with each other of a polymerizable organic functional group- and crosslinking group-containing curable organopolysiloxane, by coating, on a fiber-reinforced film made of a cured organopolysiloxane resin which is transparent in the visible region and obtained by a crosslinking reaction between (A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydrosilylation reaction catalyst;
(II) forming a transparent inorganic layer selected from the group consisting of a silicon oxynitride layer, silicon nitride layer, and silicon oxide layer, by vapor deposition, on the cured organopolysiloxane layer;
(III) forming a cured polymer layer, by coating, on the transparent inorganic layer; and then
(IV) forming a transparent inorganic layer selected from the group consisting of a silicon oxynitride layer, silicon nitride layer, and silicon oxide layer, by vapor deposition, on the cured polymer layer.

14. The method of producing a cured organopolysiloxane resin film having gas barrier properties according to claim 13, wherein the cured organopolysiloxane layer (a), the cured organopolysiloxane layer (b), and the cured organopolysiloxane layer (c) are formed by a condensation reaction or hydrosilylation reaction, the cured organopolysiloxane layer (d) is formed by polymerization between polymerizable organic functional groups by means of high energy ray irradiation or actinic energy ray irradiation or heating, the cured organopolysiloxane layer (e) is formed by a condensation reaction or hydrosilylation reaction and by polymerization between polymerizable organic functional groups by means of high energy ray irradiation or actinic energy ray irradiation or heating
and the cured polymer layer is formed by irradiating ultraviolet ray on a ultraviolet ray-curable monomer, oligomer or polymer in the presence of a photopolymerization initiator, irradiating electron beam on an electron beam-curable monomer, oligomer or polymer, or heating a heat-curable monomer, oligomer or polymer.

15. A cured organopolysiloxane resin film having gas barrier properties, the cured organopolysiloxane resin film comprising a fiber-reinforced film made of a cured organopolysiloxane resin which is transparent in the visible region and obtained by a crosslinking reaction between (A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in the presence of (C) a hydrosilylation reaction catalyst, and a silicon oxynitride layer that is formed on the fiber-reinforced film, wherein a molar ratio of hydrosilyl groups of component (B) to unsaturated aliphatic hydrocarbyls of component (A) is within the range of 1.05 to 1.50, and the cured organopolysiloxane resin has hydrosilyl groups; a cured polymer layer is formed on the silicon oxynitride layer; and a silicon oxynitride layer is formed on the cured polymer layer.

16. A cured organopolysiloxane resin film having gas barrier properties according to claim 15, wherein the cured polymer is an ultraviolet ray-cured polymer, electron beam-cured polymer, or heat-cured polymer, the fiber reinforcement in the fiber-reinforced film comprises an inorganic fiber or synthetic fiber, and is in the form of a single fiber, thread, woven cloth or non-woven cloth.

17. A method of producing the cured organopolysiloxane resin film having gas barrier properties according to claim 15, the method comprising
(I) forming a silicon oxynitride layer, by reactive ion plating, on a fiber-reinforced film made of a hydrosilyl group-containing cured organopolysiloxane resin which is transparent in the visible region and obtained by a crosslinking reaction between (A) an organopolysiloxane resin that is represented by the average siloxane unit formula
RₐSiO_{(4-a)/2} (1)
wherein R is a C₁ to C₁₀ monovalent hydrocarbyl and a is a number with an average value in the range of 0.5<a<2 and that has an average of at least 1.2 C₂ to C₁₀ unsaturated aliphatic hydrocarbyls per molecule and (B) an organosilicon compound having at least two silicon-bonded hydrogen atoms per molecule in an amount sufficient to provide a molar ratio of hydrosilyl groups of component (B) to unsaturated aliphatic hydrocarbyls of component (A) within the range of 1.05 to 1.50 in the presence of (C) a hydro silylation reaction catalyst,
(II) forming a cured polymer layer, by coating, on the silicon oxynitride layer, and then
(III) forming a silicon oxynitride layer, by reactive ion plating, on the cured polymer layer.

18. The method of producing a cured organopolysiloxane resin film having gas barrier properties according to claim 17, wherein the cured polymer layer is formed by irradiating ultraviolet ray on a ultraviolet ray-curable monomer, oligomer or polymer in the presence of a photopolymerization initiator, irradiating electron beam on an electron beam-curable monomer, oligomer or polymer, or heating a heat-curable monomer, oligomer or polymer.

19. The cured organopolysiloxane resin film having gas barrier properties according to claim 5, wherein the fiber reinforcement is in the form of a single fiber, yarn, woven cloth or non-woven cloth.
